(19) United States
(12) Patent Application Publication
(10) Pub. No.: US 2026/0190697 A1
(43) Pub. Date: Jul. 2, 2026

(54) DISPLAY DEVICE

(71) Applicant: LG Display Co., Ltd., Seoul (KR)

(72) Inventors: Seonhee LEE, Paju-si (KR); Wonyeol CHOI, Paju-si (KR); Sukhyun KANG, Paju-si (KR); Juyoung PARK, Paju-si (KR)

(73) Assignee: LG Display Co., Ltd., Seoul (KR)

(21) Appl. No.: 19/337,251

(22) Filed: Sep. 23, 2025

(30) Foreign Application Priority Data
Dec. 30, 2024 (KR) 10-2024-0199649

(51) Int. Cl. H10K 59/131; H10K 59/121; H10K 59/123; H10K 59/88

(52) U.S. Cl. CPC H10K 59/131; H10K 59/1213; H10K 59/123; H10K 59/88

(57) ABSTRACT

The present disclosure provides a display device including a substrate having a display area with a light emitting area and a non-light emitting area, and a non-display area adjacent to the display area. A common voltage line is disposed in the display area, a pixel electrode is disposed in the light emitting area, and a conductive pattern is disposed in the non-light emitting area and electrically connected to the common voltage line. A bank includes a first opening corresponding to the light emitting area and a second opening corresponding to a portion of the conductive pattern. An intermediate layer is disposed on the pixel electrode and the bank and includes a third opening corresponding to the second opening. A common electrode is disposed on the intermediate layer and the bank and is electrically connected to the conductive pattern through the second opening and the third opening, enabling low power driving.

### CROSS REFERENCE TO RELATED APPLICATION

This application claims priority from Korean Patent Application No. 10-2024-0199649, filed on Dec. 30, 2024 in the Korean Intellectual Property Office, which is hereby incorporated by reference for all purposes as if fully set forth herein.

### BACKGROUND

### Technical Field

The present disclosure relates to electronic devices, and more specifically, to display devices.

### Description of the Related Art

In today's information society, display devices for presenting images or visual information to users are increasingly important. The need for such display devices have caused display technology to be rapidly developed, and various types or usages of display devices have been developed. In addition, as display devices are becoming thinner and lighter, usages of the display devices are increasingly expanding, and displays are widely being applied in various fields of devices, apparatuses, and systems.

Display devices tend to add various functions including functions interoperated or associated with other devices, apparatuses, and systems, as well as stand-alone functions, even when an area occupied by a display area for displaying images is increased.

As the so-called bezel-less or bezel-free designs that make the display area appear full are increasingly becoming popular, recently work has been progressing on reducing an area of a non-display area outside of the display area.

### BRIEF SUMMARY

The disclosure focuses on a configuration where the cathode contact area is placed inside the display area rather than the non-display area. This arrangement allows the common electrode to be connected to the common voltage line within the active region, ensuring stable voltage delivery across all pixels. As a result, the display can achieve uniform luminance, higher resolution through reduced spacing between subpixels, and narrower bezels since the border area does not need to accommodate the cathode contacts.

Additional aspects include the use of multiple layers with carefully defined openings in the bank and intermediate layers to enable efficient electrical coupling without interfering with the light-emitting areas. Certain embodiments also use sacrificial layers to improve manufacturing reliability and embed touch sensors within the panel to support thinner, fully integrated displays. A layered encapsulation structure composed of organic and inorganic materials protects the light-emitting elements from moisture and oxygen while preserving flexibility.

Overall, the structure supports advanced displays such as foldable, rollable, and curved formats while maintaining low power consumption, high brightness, and compact form factors. The combination of improved electrical connection strategies, optimized layer configurations, and integrated sensing capabilities provides a significant advancement in display technology.

For example, one or more aspects of the present disclosure may provide a display device that includes a structure where a cathode contact area electrically connecting a common electrode and a common voltage line to each other is disposed in a display area, and is capable of improving an unevenness in luminance between areas in the display area.

One or more aspects of the present disclosure may provide a display device that includes a structure where a cathode contact area electrically connecting a common electrode and a common voltage line to each other is disposed in a display area, and is capable of reducing a distance between subpixels (e.g., a width of a non-light emitting area) and thereby achieving high resolution.

One or more aspects of the present disclosure may provide a display device that includes a structure where a cathode contact area electrically connecting a common electrode and a common voltage line to each other is not disposed in a non-display area, and is capable of implementing a narrow bezel by reducing a bezel width.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can be provided that includes a substrate including a display area including a light emitting area and a non-light emitting area, and a non-display area surrounding the display area, a common voltage line disposed in the display area, a pixel electrode disposed in the light emitting area, a conductive pattern disposed in the non-light emitting area and electrically connected to the common voltage line, a bank including a first opening located to correspond to the light emitting area and a second opening located to correspond to a portion of the conductive pattern, an intermediate layer located on the pixel electrode and the bank and including a third opening located to correspond to the second opening, and a common electrode disposed on the intermediate layer and the bank and electrically connected to the conductive pattern through the second opening and the third opening.

According to one or more example embodiments of the present disclosure, a display device can be provided that includes a substrate including a display area including a light emitting area and a non-light emitting area, and a non-display area surrounding the display area, a common voltage line disposed in the display area, a pixel electrode disposed in the light emitting area, a conductive pattern disposed in the non-light emitting area and electrically connected to the common voltage line, a bank including a first opening located corresponding to the light emitting area, a first sub-opening located to correspond to a portion of the conductive pattern, and a second sub-opening located to be spaced from the first sub-opening and located in the non-light emitting area, a sacrificial layer disposed in the second sub-opening, an intermediate layer disposed on the pixel electrode, the bank, and the sacrificial layer, and including a third opening located to correspond to the first sub-opening, and a common electrode disposed on the intermediate layer and the bank, and electrically connected to the conductive pattern through the first sub-opening and the third opening.

According to one or more aspects of the present disclosure, a display device may be provided that is capable of improving an unevenness in luminance between areas in a display area by including a structure where a cathode contact area electrically connecting a common electrode and a common voltage line to each other is disposed in the display area.

According to one or more aspects of the present disclosure, a display device may be provided that is capable of reducing a distance between subpixels (e.g., a width of a non-light emitting area) and thereby achieving high resolution by including a structure where a cathode contact area electrically connecting a common electrode and a common voltage line to each other is disposed in a display area.

According to one or more aspects of the present disclosure, a display device may be provided that is capable of implementing a narrow bezel by reducing a bezel width by including a structure where a cathode contact area electrically connecting a common electrode and a common voltage line to each other is not disposed in a non-display area.

According to one or more aspects of the present disclosure, a display device may be provided that is capable of reducing a distance between subpixels, and achieving high resolution and low power driving.

Effects or advantages from aspects, examples, and embodiments described herein are not limited thereto, and additional effects or advantages will become apparent to those skilled in the art from the following description.

### BRIEF DESCRIPTION OF THE SEVERAL VIEWS OF THE DRAWINGS

The accompanying drawings, which are included to provide a further understanding of the disclosure and are incorporated in and constitute a portion of the disclosure, illustrate aspects of the disclosure and together with the description serve to explain principles of the disclosure. It should be therefore understood that aspects, examples, and embodiments described herein are not limited to the illustrations of the accompanying drawings. In the drawings:

FIG. 1 illustrates an example system configuration of a display device according to aspects of the present disclosure;

FIG. 2 illustrates an example display panel according to aspects of the present disclosure;

FIG. 3 is an example cross-sectional view of the display panel according to aspects of the present disclosure;

FIG. 4 is an example plan view of the display device according to aspects of the present disclosure;

FIG. 5 is an example cross-sectional view taken along line I-I′ of FIG. 4;

FIG. 6 is another example cross-sectional view taken along line I-I′ of FIG. 4;

FIG. 7 is an example enlarged cross-sectional view of area X in FIG. 5,

FIGS. 8 to 13 illustrate an example process of manufacturing the display device according to aspects of the present disclosure;

FIG. 14 is a plan view of a normal display device;

FIG. 15 is another plan view of a normal display device;

FIG. 16 is a cross-sectional view taken along line II-II′ of FIG. 15;

FIG. 17 illustrates a process of the display device illustrated in FIG. 16;

FIG. 18 is an example of cross-sectional views of area A in FIG. 4 and area B in FIG. 15;

FIG. 19 is an example of cross-sectional views taken along line III-III′ and line IV-IV′ of FIG. 18; and

FIGS. 20 to 22 illustrate example plan views of the display device according to aspects of the present disclosure.

### DETAILED DESCRIPTION

Reference will now be made in detail to example embodiments of the present disclosure, examples or aspects of which may be illustrated in the accompanying drawings. In the following description, the structures, implementations, methods, and operations described herein are not limited to the specific examples, aspects, and embodiments set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure.

In the following description, where the detailed description of the relevant known function or configuration may unnecessarily obscure aspects of the present disclosure, a detailed description of such known function or configuration may be omitted.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The terms such as “including,” “having,” “containing,” “constituting” and “comprising” used herein are generally intended to allow other components to be added unless the terms are used with the term “only.” As used herein, singular forms are intended to include plural forms unless the context clearly indicates otherwise.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to,” “overlaps with,” or the like a second element, it should be interpreted that, not only can the first element “be directly connected or coupled to,” “directly contact,” or “directly overlap with” the second element, but a third element can also be “interposed” between the first and second elements, or the first and second elements can “be connected or coupled to,” “overlap with,” or the like each other via a fourth element. Here, the second element may be included in at least one of two or more elements that “are connected or coupled to,” “overlap with,” or the like each other.

To further elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In addition, when any dimensions, relative sizes, etc., are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can.”

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

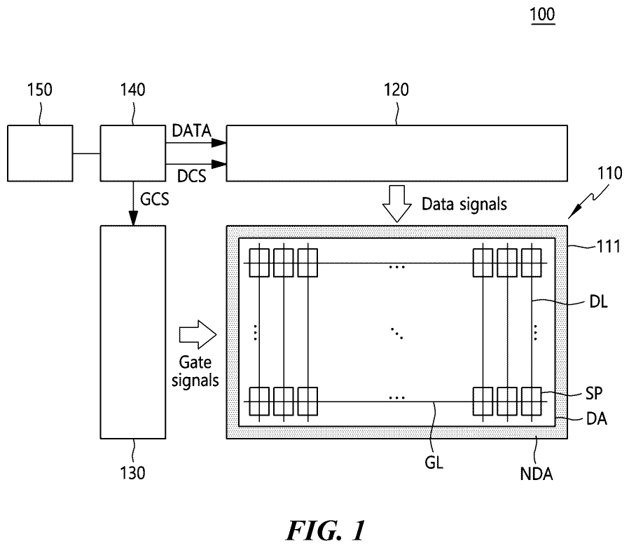

FIG. 1 illustrates an example system configuration of a display device 100 according to aspects of the present disclosure.

Referring to FIG. 1, in one or more example embodiments, the display device 100 may include a display panel 110 and at least one display driving circuit, as elements for display images. The at least one display driving circuit may be a circuit for driving the display panel 110, and include a data driving circuit 120, a gate driving circuit 130, a controller 140, and other circuit components.

The display panel 110 may include a substrate 111 and a plurality of subpixels SP disposed on the substrate 111.

The substrate 111 may include a display area DA allowing an image to be displayed and a non-display area NDA around an outer edge of the display area DA.

The display area DA may also be referred to as an active area, and a plurality of subpixels SP for displaying images may be disposed in the display area DA. The non-display area NDA may also be referred to as a non-active area and include a pad area.

In one or more aspects, the display panel 110 may be configured to have a very small non-display area NDA. The non-display area NDA may be also referred to as a “bezel” or “bezel area.” For example, the non-display area NDA may include a first non-display area located outside of the display area DA in a first direction, a second non-display area located outside of the display area DA in a second direction, a third non-display area located outside of the display area DA in a direction opposite to the first direction, and a fourth non-display area located outside of the display area DA in a direction opposite to the second direction.

The first non-display area among the first to fourth non-display areas may include a pad area to which one or more driving circuits are connected or bonded. Among the first to fourth non-display areas, the second to fourth non-display areas may have a very small size compared to the first non-display area.

In one or more aspects, a boundary area may be defined between the display area DA and the non-display area NDA. For example, the boundary area may be bent at a certain angle to the display area DA, and thereby, at least a portion of the non-display area NDA may be located under the display area DA. In this implementation, when a user views the display device 100 in front thereof, all or most of the non-display area NDA may be invisible to the user. For example, the first non-display area may include a bending area. As the bending area is bent, the first non-display area may be invisible in front of the display device 100.

Several types of signal lines for driving a plurality of subpixels SP may be disposed on the substrate 111 of the display panel 110.

In one or more aspects, the display device 100 herein may be a liquid crystal display device, or the like, or a self-emissive display device in which light is emitted from the display panel 110 itself. In an example where the display device 100 is the self-emissive display device, each of the plurality of subpixels SP may include a light emitting element.

For example, the display device 100 according to aspects of the present disclosure may be an organic light emitting display device in which light emitting elements are implemented using organic light emitting diodes (OLED). In another example, the display device 100 according to aspects of the present disclosure may be an inorganic light emitting display device in which light emitting elements are implemented using inorganic material-based light emitting diodes. In another example, the display device 100 according to aspects of the present disclosure may be a quantum dot display device in which the light emitting element is implemented using quantum dots, which are self-emission semiconductor crystals. But aspects of the present disclosure are not limited thereto.

The structure of each or at least one of a plurality of subpixels SP included in the display device 100 may depend on types of the display device 100. For example, when the display device 100 is a self-emissive display device including self-emissive subpixels SP, each subpixel SP may include a self-emissive light emitting element, one or more transistors, and one or more capacitors.

The several types of signal lines may include, for example, a plurality of data lines DL for carrying data signals (which may be referred to as data voltages or image signals), a plurality of gate lines GL for carrying gate signals (which may be referred to as scan signals), and the like.

In one or more aspects, the plurality of data lines DL and the plurality of gate lines GL may intersect one another. Each of the plurality of data lines DL may be configured to extend in a first direction, and each of the plurality of gate lines GL may be configured to extend in a second direction. For example, the first direction may be the column direction, and the second direction may be the row direction. In another example, the first direction may be the row direction, and the second direction may be the column direction. Hereinafter, for merely convenience of explanation, discussions are provided based on examples where the first direction is the column direction and the second direction is the row direction. Hereinafter, for convenience of explanation, discussions may be provided based on examples where each of a plurality of data lines DL is disposed in the column direction, and each of a plurality of gate lines GL is disposed in the row direction, but aspects of the present disclosure are limited thereto.

The data driving circuit 120 may be a circuit for driving a plurality of data lines DL and can output data signals to the plurality of data lines DL.

The data driving circuit 120 can receive image data DATA in digital form from the controller 140, convert the received image data DATA into data signals in analog form, and output the resulting data signals to the plurality of data lines DL.

In one or more aspects, the data driving circuit 120 may be connected to the display panel 110 by a tape-automated-bonding (TAB) technology, or connected to a conductive pad such as a bonding pad of the display panel 110 by a chip-on-glass (COG) technology or a chip-on-panel (COP) technology, or connected to the display panel 110 by a chip-on-film (COF) technology. However, aspects of the present disclosure are not limited thereto.

In one or more aspects, the data driving circuit 120 may be located in, and/or connected to, but not limited to, only one side or edge (e.g., an upper portion or a lower portion) of the display panel 110. In one or more aspects, the data driving circuit 120 may be disposed in, and/or electrically connected to, but not limited to, two sides or edges (e.g., an upper portion and a lower portion) of the display panel 110 or at least two of four sides or edges (e.g., the upper portion, the lower portion, a left portion, and a right portion) of the display panel 110 according to driving schemes, panel design schemes, or the like.

The data driving circuit 120 may be connected to an area outward from the display area DA of the display panel 110, or be disposed in the display area DA of the display panel 110.

The gate driving circuit 130 may be a circuit configured to drive a plurality of gate lines GL and can output gate signals to the plurality of gate lines GL.

The gate driving circuit 130 can receive several types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In one or more aspects, the gate driving circuit 130 included in the display device 100 may be embedded into the display panel 110 by a gate-in-panel (GIP) technique. In an example where the gate driving circuit 130 is implemented by the gate-in-panel (GIP) technique, the gate driving circuit 130 may be disposed on the substrate 111 of the display panel 110 during the manufacturing process of the display panel 110 or display device 100.

In one or more aspects, the gate driving circuit 130 may be disposed in the non-display area NDA of the display panel 110.

In one or more aspects, the gate driving circuit 130 may be disposed in the display area DA of the display panel 110. In this implementation, for example, the gate driving circuit 130 may be disposed in, and/or electrically connected to, but not limited to, a first area (e.g., a left area or a right area) of the display area DA of the display panel 110. In one or more aspects, the gate driving circuit 130 may be disposed in, and/or electrically connected to, but not limited to, a first partial area (e.g., a left portion or a right portion) in the display area DA, and a second partial area (e.g., the right portion or the left portion) in the display area DA.

Herein, the gate driving circuit 130 embedded in the display panel 110 by the gate-in-panel (GIP) technique may also be referred to as a “gate-in-panel circuit.”

The controller 140 may be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 may be implemented in a separate component from the data driving circuit 120, or integrated with the data driving circuit 120, so that the controller 140 and the data driving circuit 120 can be implemented in a single integrated circuit.

The controller 140 may be a timing controller used in the typical display technology or a control apparatus/device capable of additionally performing other control functionalities in addition to the typical function of the timing controller. In one or more embodiments, the controller 140 may be one or more other control circuits different from the timing controller, or a circuit or component in the control apparatus/device. The controller 140 may be implemented using various circuits or electronic components such as an integrated circuit (IC), a field programmable gate array (FPGA), an application specific integrated circuit (ASIC), a processor, and/or the like. However, aspects of the present disclosure are not limited thereto.

The controller 140 may be mounted on a printed circuit board, a flexible printed circuit, or the like, and may be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces may include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display device 100 may include a touch sensor, and a touch sensing circuit configured to sense the touch sensor and detect whether a touch is applied by an object such as a finger, a pen, or the like, or a location of the touch (or touch coordinates).

The touch sensing circuit may include a touch driving circuit configured to drive and sense the touch sensor and generate and output touch sensing data, and a touch controller configured to detect whether a touch is applied or a location of the touch (or touch coordinates) based on the touch sensing data.

The touch sensor may include a plurality of touch electrodes. The touch sensor may further include a plurality of touch lines for electrically connecting the plurality of touch electrodes to the touch driving circuit.

The touch sensor may be disposed outside of the display panel 110 in the form of a touch panel or may be disposed inside of the display panel 110. The touch sensor disposed outside of the display panel 110 may be referred to as an add-on type of touch sensor. In the example where the add-on type of touch sensor is disposed in the display device 100, the touch panel and the display panel 110 may be separately manufactured and combined in an assembly process. The add-on type of touch panel may include a touch panel substrate and a plurality of touch electrodes disposed on the touch panel substrate.

In the example where the touch sensor is disposed inside of the display panel 110, the touch sensor may be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing technique or a mutual-capacitance sensing technique.

In the example where the touch sensing circuit performs touch sensing by the self-capacitance sensing technique, the touch sensing circuit can perform touch sensing based on capacitance between each touch electrode and a touch object (e.g., a finger, a pen, and the like). According to the self-capacitance sensing technique, each of a plurality of touch electrodes can serve as both a driving touch electrode and a sensing touch electrode. The touch driving circuit may drive all, or one or more, of a plurality of touch electrodes and sense all, or one or more, of the plurality of touch electrodes.

In the example where the touch sensing circuit performs touch sensing by the mutual-capacitance sensing technique, the touch sensing circuit can perform touch sensing based on a capacitance between touch electrodes. According to the mutual-capacitance sensing technique, a plurality of touch electrodes may be divided into driving touch electrodes and sensing touch electrodes. The touch driving circuit can drive the driving touch electrodes and sense the sensing touch electrodes.

In one or more aspects, the touch driving circuit and touch controller included in the touch sensing circuit may be implemented in separate devices or in a single device. In one or more aspects, the touch driving circuit and the data driving circuit may be implemented in separate devices or in a single device.

The display device 100 may further include a power supply circuit for supplying several types of power to the display driving circuit and/or the touch sensing circuit.

In one or more aspects, the display device 100 may be a mobile terminal such as a smart phone, a tablet, or the like, or a monitor, a television (TV), or the like. Further, the display device 100 may be configured with various types, sizes, and shapes to display information or images. For example, the display device 100 may be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

In one or more aspects, the display device 100 may further include an electronic device such as a camera (e.g., an image sensor), an electronic unit or device such as a sensor capable of detecting an object, ambient light, etc., and the like. For example, the sensor may be a sensor capable of detecting an object or a human body by receiving light such as infrared light, ultrasonic light, ultraviolet light or the like.

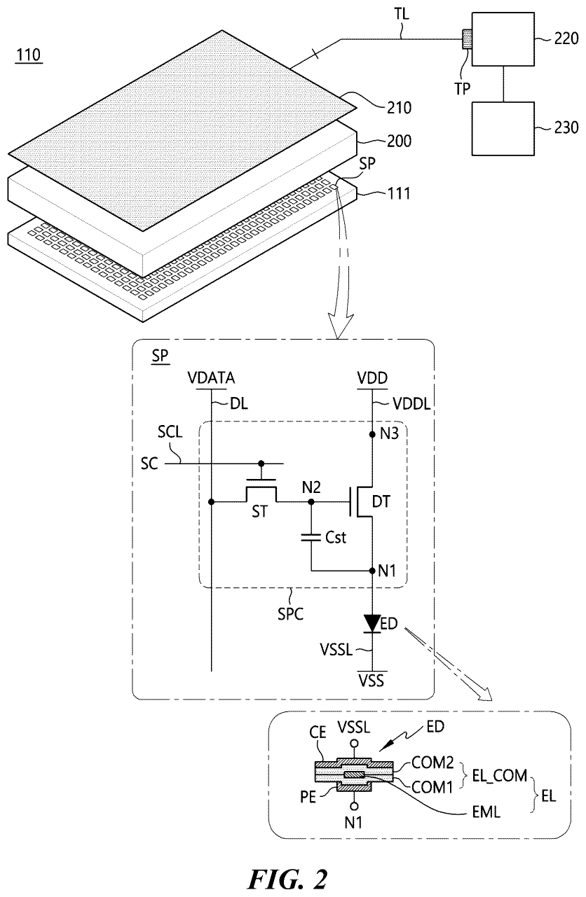

FIG. 2 illustrates an example configuration of the display panel 110 according to aspects of the present disclosure. In discussions that follow for the configuration of FIG. 2, discussions for features and configurations equal, substantially equal, or similar to the features and configurations described with reference to FIG. 1 are omitted or briefly described for conciseness.

Referring to FIG. 2, in one or more example embodiments, the display panel 110 may include a substrate 111 on which a plurality of subpixels SP are disposed, and an encapsulation layer 200 over the substrate 111. The encapsulation layer 200 may also be referred to as an encapsulation substrate, an encapsulation part, or the like.

Referring to FIG. 2, in an example where the display device 100 is a self-emissive display device, each of the plurality of subpixels SP disposed on the substrate 111 may include a light emitting element ED and a subpixel circuit SPC for driving the light emitting element ED.

Referring to FIG. 2, the subpixel circuit SPC may include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors may include a driving transistor DT configured to drive the light emitting element ED and a scan transistor ST configured to be turned on or off by a scan signal SC.

The driving transistor DT can supply a driving current to the light emitting element ED.

The scan transistor ST may be configured to control an electrical state of a corresponding node in the subpixel circuit SPC or to control the state or operation of the driving transistor DT.

The at least one capacitor may include a storage capacitor Cst configured to maintain a voltage at a constant level during a display frame or a period of the display frame.

To drive at least one subpixel SP, at least one data signal VDATA, which is an image signal, and at least one scan signal SC, which is a gate signal, may be applied to the at least one subpixel SP. Further, to drive one or more subpixels SP, at least one common driving voltage including a first common driving voltage VDD and a second common driving voltage VSS may be applied to the one or more subpixels SP.

The light emitting element ED may include a pixel electrode PE, an intermediate layer EL, and a common electrode CE. The intermediate layer EL may be disposed between the pixel electrode PE and the common electrode CE.

For example, the pixel electrode PE may be an electrode disposed in each subpixel SP, and the common electrode CE may be an electrode disposed commonly in all or some of a plurality of subpixels SP. For example, the pixel electrode PE may be an anode electrode, and the common electrode CE may be a cathode electrode. In another example, the pixel electrode PE may be a cathode electrode, and the common electrode CE may be an anode electrode. Hereinafter, for convenience of explanation, discussions may be provided based on examples where the pixel electrode PE is an anode electrode, and the common electrode CE is a cathode electrode.

The pixel electrode PE may include a metal, an alloy of one or more metals, or a combination of a metal and an oxide metal. For example, the pixel electrode PE may include a multilayer structure including a transparent conductive layer and an opaque conductive layer with high reflection efficiency. The transparent conductive layer of the pixel electrode PE may include a material having a relatively high work function value, such as indium-tin-oxide (ITO) or indium-zinc-oxide (IZO). The opaque conductive layer may be in the form of a single layer of any one selected from the group of silver (Ag), aluminum (Al), copper (Cu), molybdenum (Mo), titanium (Ti), nickel (Ni), chromium (Cr), tungsten (W), and an alloy of two or more thereof, or be in the form of a multilayer of any one or more selected from the group of silver (Ag), aluminum (Al), copper (Cu), molybdenum (Mo), titanium (Ti), nickel (Ni), chromium (Cr), tungsten (W), and/or one or more alloys of two or more thereof. For example, the pixel electrode PE may include a structure in which a transparent conductive layer, an opaque conductive layer, and a transparent conductive layer are sequentially stacked, or may include a structure in which a transparent conductive layer and an opaque conductive layer are sequentially stacked.

The common electrode CE may include a transparent conductive material such as indium tin oxide (ITO) or indium zinc oxide (IZO), or may include silver (Ag), aluminum (Al), magnesium (Mg), calcium (Ca) or an alloy thereof having a thickness thin enough to allow light to be transmitted.

In an example where the light emitting element ED is an organic light emitting diode, the intermediate layer EL may include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 may be referred to as a common intermediate layer EL_COM.

In one or more aspects, the emission layer EML may be disposed for each subpixel SP, and the common intermediate layer EL_COM may be commonly disposed across all or some of a plurality of subpixels SP.

The emission layer EML may be disposed in each light emitting area, and the common intermediate layer EL_COM may be disposed commonly across all or some of a plurality of light emitting areas and all or some of a plurality of non-light emitting areas.

For example, the first common intermediate layer COM1 may include a hole injection layer (HIL), a hole transport layer (HTL), and the like. The second common intermediate layer COM2 may include an electron transport layer (ETL), an electron injection layer (EIL), and the like.

The hole injection layer can inject holes from the pixel electrode PE to the hole transport layer, the hole transport layer can transport holes to the emission layer EML. The electron injection layer can inject electrons from the common electrode CE to the electron transport layer, and the electron transport layer can transport electrons to the emission layer EML.

In one or more aspects, the common electrode CE may be electrically connected to a second common driving voltage line VSSL. A second common driving voltage VSS may be applied to the common electrode CE through the second common driving voltage line VSSL. The pixel electrode PE may be electrically connected directly or indirectly (via another transistor) to a first node N1 of the corresponding driving transistor DT of each subpixel SP. Herein, the second common driving voltage VSS may also be referred to as a “base voltage,” and the second common driving voltage line VSSL may also be referred to as a “low power supply voltage line,” a “low voltage line,” or a “base voltage line.”

Each light emitting element ED may be configured by overlapping of a pixel electrode PE, an emission layer EML in an intermediate layer EL, and a common electrode CE. A respective light emitting area may be formed by each light emitting element ED. For example, a respective light emitting area of each light emitting element ED may include an area where a pixel electrode PE, an emission layer EML in an intermediate layer EL, and a common electrode CE overlap with each other

In one or more aspects, each or at least one of a plurality of light emitting elements ED included in the display panel 110 or the display device 100 may be an organic light emitting diode (OLED), an inorganic light emitting diode (LED), a quantum dot (QD) light emitting element, a micro light emitting diode, a mini light emitting diode, or the like, but aspects of the present disclosure are not limited thereto. In the example where each light emitting element ED is an organic light emitting diode (OLED), the intermediate layer EL of a corresponding light emitting element ED may be a layer including an organic material.

Referring to FIG. 2, the driving transistor DT may be a transistor configured to supply a driving current to the light emitting element ED. The driving transistor DT may be connected between a first common driving voltage line VDDL and the light emitting element ED.

The driving transistor DT may include a first node N1, a second node N2, and a third node N3. The first node N1 may be electrically connected to the light emitting element ED. A data signal VDATA may be applied to the second node N2. A first common driving voltage VDD delivered through the first common driving voltage line VDDL may be applied to the third node N3.

In the driving transistor DT, the second node N2 may be a gate node, the first node N1 may be a source node or a drain node, and the third node N3 may be the drain node or the source node. Hereinafter, for merely convenience of explanation, discussions may be provided based on examples where the first, second, and third nodes (N1, N2, and N3) of the driving transistor DT are source, gate, and drain nodes, respectively. However, aspects of the present disclosure are not limited thereto.

The scan transistor ST included in the subpixel circuit SPC illustrated in FIG. 2 may be a switching transistor for transferring a data signal VDATA, which is an image signal, to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST may be electrically connected to the data line DL. The source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed to be located outside of the driving transistor DT, and therefore, be different from an internal capacitor such as a parasitic capacitor (e.g., a gate-source capacitor Cgs, a gate-drain capacitor Cgd) that may be formed between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

In an example where the display panel 110 has the top emission structure, at least a portion of the subpixel circuit SPC may overlap with at least a portion of the light emitting element ED in the vertical direction. In this configuration, the area or size of a corresponding light emitting area can increase, and a corresponding aperture ratio can increase.

In an example where the display panel 110 has the bottom emission structure, the subpixel circuit SPC may not overlap with the light emitting element ED in the vertical direction.

As shown in FIG. 2, the subpixel circuit SPC may include two transistors (2T: DT and ST) and one capacitor (1C: Cst) (which may be referred to as a “2T1C structure”), and in some implementations, may further include one or more transistors, and/or further include one or more capacitors.

For example, the subpixel circuit SPC may have an 8T1C structure including 8 transistors and 1 capacitor. In another example, the subpixel circuit SPC may have an 6T2C structure including 6 transistors and 2 capacitor. In another example, the subpixel circuit SPC may have an 7T1C structure including 7 transistors and 1 capacitor. However, aspects of the present disclosure are not limited to such specific structures.

The types and number of gate signals supplied to a subpixel SP, and/or the types and number of gate lines connected to the subpixel SP may vary depending on a structure of a corresponding subpixel circuit SPC. Further, the types and number of common driving voltages supplied to a subpixel SP may vary depending on a structure of a corresponding subpixel circuit SPC.

Referring to FIG. 2, since circuit elements (e.g., a light emitting element ED such as an organic light emitting diode (OLED) including an organic material) in each subpixel SP may be easily damaged by external moisture or oxygen, an encapsulation layer 200 may be disposed in the display panel 110 to prevent the external moisture or oxygen from penetrating the circuit elements (e.g., the light emitting element ED).

The encapsulation layer 200 may be disposed in various shapes or configurations to prevent light emitting elements ED from contacting moisture or oxygen. For example, the encapsulation layer 200 may include two or more layers in which one or more organic layers and one or more inorganic layers are alternately stacked, but aspects of the present disclosure are not limited thereto.

Referring to FIG. 2, in one or more aspects, to sense a touch of a user, the display device 100 may include a touch sensor layer 210 including a plurality of sensor electrodes, a touch driving circuit 220 configured to sense the plurality of sensor electrodes, and a touch controller 230 configured to determine whether a touch is applied or a location of the touch (e.g., touch coordinates) based on the sensing result (e.g., touch sensing data) of the touch driving circuit 220.

The touch sensor layer 210 may be embedded in the display panel 110. For example, the touch sensor layer 210 may be disposed on the encapsulation layer 200 of the display panel 110.

The display panel 110 may include a plurality of touch pads TP to which the touch driving circuit 220 is electrically connected, and a plurality of touch lines TL for electrically connecting the plurality of sensor electrodes included in the touch sensor layer 210 to the plurality of touch pads TP to which the touch driving circuit 220 is connected.

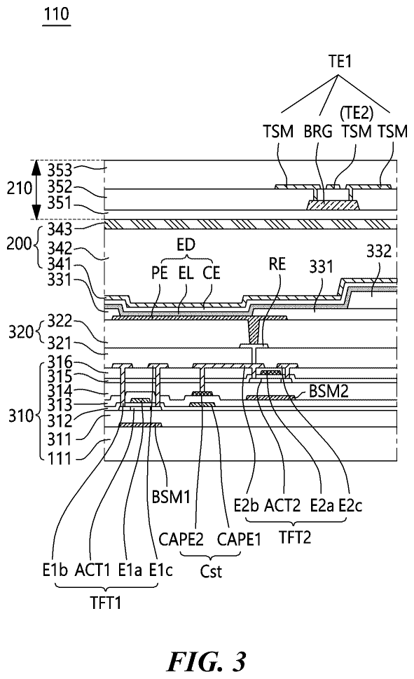

FIG. 3 is an example cross-sectional view of the display panel 110 according to aspects of the present disclosure. In discussions that follow for the configuration of FIG. 3, discussions for features and configurations equal, substantially equal, or similar to the features and configurations described with reference to FIGS. 1 and 2 are omitted or briefly described for conciseness.

Referring to FIG. 3, in one or more example embodiments, in terms of stack-up structure, the display panel 110 may include a transistor part, a light emitting element part, and an encapsulation part.

The substrate 111 may be in the form of a single layer or a multilayer. In an example where the substrate 111 includes a multilayer, the substrate 111 may include a first substrate, a substrate intermediate layer, and a second substrate. The substrate intermediate layer may be located between the first substrate and the second substrate. For example, each of the first substrate and the second substrate may be a polyimide (PI) layer. The substrate intermediate layer may be an inorganic insulating layer. When electric charges are stored on the first substrate which is a polyimide (PI) layer, the substrate intermediate layer can block the charges from affecting transistors on the second substrate through the second substrate, which is a polyimide (PI) layer.

In addition, the substrate intermediate layer can block moisture from penetrating upwardly through the first substrate. For example, the substrate intermediate layer may be in the form of a single layer of silicon nitride (SiNx) or silicon oxide (SiOx) or a multilayer of silicon nitride (SiNx) and/or silicon oxide (SiOx), or may be in the form of a double layer of silicon dioxide (SiO₂) and silicon nitride (SiNx). However, aspects of the present disclosure are not limited thereto.

The transistor part may include the substrate 111, and several types of insulating layers (311, 312, 313, 314, 315, and 316), several types of transistors (TFT1 and TFT2), a storage capacitor Cst, and various electrodes or signal lines, which are disposed on the substrate 111.

The transistors (TFT1 and TFT2) included in the transistor part may include a first transistor TFT1 and a second transistor TFT2.

The first transistor TFT1 may include a first active layer ACT1, a first electrode E1a, a second electrode E1b, and a third electrode E1c. The first active layer ACT1 may be a first semiconductor layer, but aspects of the present disclosure are not limited thereto. For example, the first active layer ACT1 may include an oxide semiconductor, amorphous silicon, polysilicon, low-temperature polysilicon (LTPS), or the like, but aspects of the present disclosure are not limited thereto. The first transistor TFT1 may be a p-channel transistor or an n-channel transistor, but aspects of the present disclosure are not limited thereto.

The first electrode E1a may be a gate electrode, the second electrode E1b may be a source electrode or a drain electrode, and the third electrode E1c may be the drain electrode or the source electrode. Hereinafter, for convenience of explanation, discussions may be provided based on examples where the first, second, and third electrodes (E1a, E1b, and E1c) are a first gate electrode E1a, a first source electrode E1b, and a first drain electrode E1c, respectively. However, aspects of the present disclosure are not limited thereto.

The second transistor TFT2 may include a second active layer ACT2, a fourth electrode E2a, a fifth electrode E2b, and a sixth electrode E2c. The second active layer ACT2 may be a second semiconductor layer, but aspects of the present disclosure are not limited thereto. For example, the second active layer ACT2 may include an oxide semiconductor, amorphous silicon, polysilicon, low-temperature polysilicon (LTPS), or the like, but aspects of the present disclosure are not limited thereto. The second transistor TFT2 may be a p-channel transistor or an n-channel transistor, but aspects of the present disclosure are not limited thereto.

For example, one of the first transistor TFT1 and the second transistor TFT2 may include an active layer including an oxide semiconductor. For example, one of the first transistor TFT1 and the second transistor TFT2 may include an active layer including a low-temperature polysilicon (LTPS). For example, each of the first transistor TFT1 and the second transistor TFT2 may include an active layer including an oxide semiconductor. For example, each of the first transistor TFT1 and the second transistor TFT2 may include an active layer including a low-temperature polysilicon (LTPS). For example, among the first transistor TFT1 and the second transistor TFT2, a driving transistor DT may include an oxide semiconductor as the active layer, and a scan transistor ST may include a low-temperature polysilicon as the active layer. For example, among the first transistor TFT1 and the second transistor TFT2, a driving transistor DT may include a low-temperature polysilicon as the active layer, and a scan transistor ST may include an oxide semiconductor as the active layer. For example, a transistor included in the gate driving circuit 130 implemented by the gate-in-panel (GIP) technique may include an oxide semiconductor or a low-temperature polysilicon as the active layer. For example, all transistors disposed on the substrate 111 and all transistors included in the gate driving circuit 130 implemented by the gate-in-panel (GIP) technique may include an oxide semiconductor as the active layer.

The fourth electrode E2a may be a gate electrode, the fifth electrode E2b may be a source electrode or a drain electrode, and the sixth electrode E2c may be the drain electrode or the source electrode. Hereinafter, for convenience of explanation, discussions may be provided based on examples where the fourth, fifth, and sixth electrode E2a, E2b, and E2c is a second gate electrode E2a, a second source electrode E2b, and a second drain electrode E2c, respectively. However, aspects of the present disclosure are not limited thereto.

The second active layer ACT2 of the second transistor TFT2 may be disposed higher from the substrate 111 than the first active layer ACT1 of the first transistor TFT1.

A first buffer layer 311 may be disposed under the first active layer ACT1 of the first transistor TFT1, and a second buffer layer 314 may be disposed under the second active layer ACT2 of the second transistor TFT2. For example, the first active layer ACT1 of the first transistor TFT1 may be disposed on the first buffer layer 311, and the second active layer ACT2 of the second transistor TFT2 may be disposed on the second buffer layer 314. The second buffer layer 314 may be disposed on the first buffer layer 311.

A storage capacitor Cst may be disposed in several metal layers in the display panel 110. For example, the storage capacitor Cst may include a first capacitor electrode CAPE1 and a second capacitor electrode CAPE2.

The light emitting element part may include a plurality of light emitting elements ED disposed on at least one planarization layer 320. Each of the plurality of light emitting elements ED may include a pixel electrode PE, an intermediate layer EL, and a common electrode CE.

The encapsulation part may include an encapsulation layer 200 on the plurality of light emitting elements ED. The encapsulation layer 200 may be in the form of a single layer or a multilayer. The encapsulation part may further include at least one dam in addition to the encapsulation layer 200.

Hereinafter, the stack-up configuration of the display panel 110 according to aspects of the present disclosure will be described in more detail with reference to FIG. 3.

Referring to FIG. 3, the first buffer layer 311 may be disposed on the substrate 111. The first buffer layer 311 may be in the form of a single layer or a multilayer. In an example where the first buffer layer 311 is in the form of a multilayer, the first buffer layer 311 may include a multi-buffer layer and an active-buffer layer.

The first active layer ACT1 of the first transistor TFT1 may be disposed on the first buffer layer 311. The first active layer ACT1 may include a channel region where a channel is formed, a source connection region on a first side of the channel region, and a drain connection region on a second opposing side of the channel region.

A first gate insulating layer 312 may be disposed on the first active layer ACT1 of the first transistor TFT1. The first gate insulating layer 312 may be in the formed of, for example, a single layer including silicon nitride (SiNx) or silicon oxide (SiOx) or a multilayer including silicon nitride (SiNx) and/or silicon oxide (SiOx). However, aspects of the present disclosure are not limited thereto.

The first gate electrode E1a of the first transistor TFT1 may be disposed on the first gate insulating layer 312. The first gate electrode E1a may include a first gate metal. The first gate metal may include a single layer of any one of molybdenum (Mo), copper (Cu), titanium (Ti), aluminum (Al), chromium (Cr), gold (Au), nickel (Ni), neodymium (Nd), tungsten (W), and an alloy of two or more thereof, or a multiple layer of one or more of molybdenum (Mo), copper (Cu), titanium (Ti), aluminum (Al), chromium (Cr), gold (Au), nickel (Ni), neodymium (Nd), tungsten (W), and/or one or more alloys of two or more thereof. However, aspects of the present disclosure are not limited thereto.

A first interlayer insulating layer 313 may be disposed on the first gate electrode E1a of the first transistor TFT1. The first interlayer insulating layer 313 may be in the formed of, for example, a single layer including silicon nitride (SiNx) or silicon oxide (SiOx) or a multilayer including silicon nitride (SiNx) and/or silicon oxide (SiOx). However, aspects of the present disclosure are not limited thereto.

The second buffer layer 314 may be disposed on the first interlayer insulating layer 313. The second buffer layer 314 may be in the formed of, for example, a single layer including silicon nitride (SiNx) or silicon oxide (SiOx) or a multilayer including silicon nitride (SiNx) and/or silicon oxide (SiOx). However, aspects of the present disclosure are not limited thereto.

The second active layer ACT2 of the second transistor TFT2 may be disposed on the second buffer layer 314. The second active layer ACT2 may include a channel region where a channel is formed, a source connection region on a first side of the channel region, and a drain connection region on a second opposing side of the channel region.

A second gate insulating layer 315 may be disposed on the second active layer ACT2 of the second transistor TFT2. The second gate insulating layer 315 may be in the formed of, for example, a single layer including silicon nitride (SiNx) or silicon oxide (SiOx) or a multilayer including silicon nitride (SiNx) and/or silicon oxide (SiOx). However, aspects of the present disclosure are not limited thereto.

The second gate electrode E2a of the second transistor TFT2 may be disposed on the second gate insulating layer 315. The second gate electrode E2a may include a second gate metal. The second gate metal may include a single layer of any one of molybdenum (Mo), copper (Cu), titanium (Ti), aluminum (Al), chromium (Cr), gold (Au), nickel (Ni), neodymium (Nd), tungsten (W), and an alloy of two or more thereof, or a multiple layer of one or more of molybdenum (Mo), copper (Cu), titanium (Ti), aluminum (Al), chromium (Cr), gold (Au), nickel (Ni), neodymium (Nd), tungsten (W), and/or one or more alloys of two or more thereof. However, aspects of the present disclosure are not limited thereto.

A second interlayer insulating layer 316 may be disposed on the second gate electrode E2a of the second transistor TFT2. The second interlayer insulating layer 316 may be in the formed of, for example, a single layer including silicon nitride (SiNx) or silicon oxide (SiOx) or a multilayer including silicon nitride (SiNx) and/or silicon oxide (SiOx). However, aspects of the present disclosure are not limited thereto.

The first source electrode E1b and the first drain electrode E1c of the first transistor TFT1 and the second source electrode E2b and the second drain electrode E2c of the second transistor TFT2 may be disposed on the second interlayer insulating layer 316.

The first source electrode E1b and the first drain electrode E1c of the first transistor TFT1 may be connected to a source connection region and a drain connection region of the first active layer ACT1, respectively, through holes of the second interlayer insulating layer 316, the second gate insulating layer 315, the second buffer layer 314, the first interlayer insulating layer 313, and the first gate insulating layer 312.

The second source electrode E2b and the second drain electrode E2c of the second transistor TFT2 may be connected to a source connection region and a drain connection region of the second active layer ACT2, respectively, through holes of the second interlayer insulating layer 316 and the second gate insulating layer 315.

The first source electrode E1b and the first drain electrode E1c of the first transistor TFT1 and the second source electrode E2b and the second drain electrode E2c of the second transistor TFT2 may include a first metal and may be disposed in a first metal layer. The first metal and the first metal layer may be referred to as a first source-drain metal and a first source-drain metal layer, respectively. The first source-drain metal may include a single layer of any one of molybdenum (Mo), copper (Cu), titanium (Ti), aluminum (Al), chromium (Cr), gold (Au), nickel (Ni), neodymium (Nd), tungsten (W), and an alloy of two or more thereof, or a multiple layer of one or more of molybdenum (Mo), copper (Cu), titanium (Ti), aluminum (Al), chromium (Cr), gold (Au), nickel (Ni), neodymium (Nd), tungsten (W), and/or one or more alloys of two or more thereof. However, aspects of the present disclosure are not limited thereto. For example, the first source-drain metal may include triple layers of Ti, Al, and Ti.

Referring to FIG. 3, in one or more aspects, the storage capacitor Cst may include the first capacitor electrode CAPE1 and the second capacitor electrode CAPE2. In one or more aspects, the storage capacitor Cst may include three or more capacitor electrodes, or two or more capacitors connected in parallel.

Each of the first capacitor electrode CAPE1 and the second capacitor electrode CAPE2 may be disposed in several metal layers in the display panel 110.

In one or more aspects, the first capacitor electrode CAPE1 may include the same first gate metal as the first gate electrode E1a of the first transistor TFT1 on the first gate insulating layer 312, and be disposed in a first gate metal layer.

In one or more aspects, the second capacitor electrode CAPE2 may be disposed on the first interlayer insulating layer 313.

The second source electrode E2b of the second transistor TFT2 may be electrically connected to the second capacitor electrode CAPE2 through holes of the second interlayer insulating layer 316, the second gate insulating layer 315, and the second buffer layer 314.

For example, the first transistor TFT1 may be the scan transistor ST of FIG. 2, and the second transistor TFT2 may be the driving transistor DT of FIG. 2.

Referring to FIG. 3, the transistor part may further include a first shield metal BSM1 disposed on the substrate 111, overlapped with the first active layer ACT1 of the first transistor TFT1, and disposed under the first active layer ACT1 of the first transistor TFT1. For example, the first shield metal BSM1 may be disposed between the substrate 111 and the first buffer layer 311, or may be disposed between the multi-buffer layer and the active buffer layer.

The transistor part may further include a second shield metal BSM2 disposed on the substrate 111, overlapped with the second active layer ACT2 of the second transistor TFT2, and disposed under the second active layer ACT2 of the second transistor TFT2.

For example, the second shield metal BSM2 may be disposed in a metal layer between the first interlayer insulating layer 313 and the second buffer layer 314. The second shield metal BSM2 may be disposed in the same metal layer as the second capacitor CAPE2.

In another example, the second shield metal BSM2 may be disposed in the same first gate metal layer as the first gate electrode E1a of the first transistor TFT1.

At least one planarization layer 320 may be disposed on the first transistor TFT1 and the second transistor TFT2. FIG. 3 illustrates, for example, two planarization layers (first and second planarization layers 321 and 322) may be disposed on the first transistor TFT1 and the second transistor TFT2. In one or more aspects, three or more planarization layers may be disposed on the first transistor TFT1 and the second transistor TFT2, but aspects of the present disclosure are not limited thereto.

Referring to FIG. 3, the first planarization layer 321 may be disposed on the first source electrode E1b and the first drain electrode E1c of the first transistor TFT1 and the second source electrode E2b and the second drain electrode E2c of the second transistor TFT2. For example, the first planarization layer 321 may be disposed such that it covers both the first transistor TFT1 and the second transistor TFT2. The first planarization layer 321 may be an organic insulating layer for flattening and protecting respective upper portions of the first transistor TFT1 and the second transistor TFT2. For example, the first planarization layer 321 may include an organic insulating material such as an acrylic resin, an epoxy resin, a phenolic resin, a polyamide resin, a polyimide resin, or the like.

Referring to FIG. 3, a relay electrode RE may be disposed on the first planarization layer 321. The relay electrode RE may be electrically connected to the second source electrode E2b of the second transistor TFT2 through a hole of the first planarization layer 321. The second source electrode E2b of the second transistor TFT2 may be electrically connected to the second capacitor electrode CAPE2 of the storage capacitor Cst.

The relay electrode RE may be disposed in a second metal layer on the first planarization layer 321, and include a second metal. The second metal and the second metal layer may be referred to as a second source-drain metal and a second source-drain metal layer, respectively. The second source-drain metal may include a single layer of any one of molybdenum (Mo), copper (Cu), titanium (Ti), aluminum (Al), chromium (Cr), gold (Au), nickel (Ni), neodymium (Nd), tungsten (W), and an alloy of two or more thereof, or a multiple layer of one or more of molybdenum (Mo), copper (Cu), titanium (Ti), aluminum (Al), chromium (Cr), gold (Au), nickel (Ni), neodymium (Nd), tungsten (W), and/or one or more alloys of two or more thereof. However, aspects of the present disclosure are not limited thereto. For example, the second source-drain metal may include triple layers of Ti, Al, and Ti.

The second planarization layer 322 may be disposed on the relay electrode RE. The second planarization layer 322 may be an organic insulating layer for flattening and protecting an upper portion of the relay electrode RE. For example, the second planarization layer 322 may include an organic insulating material such as an acrylic resin, an epoxy resin, a phenolic resin, a polyamide resin, a polyimide resin, or the like.

Referring to FIG. 3, the light emitting element part may be disposed on the second planarization layer 322. The light emitting element ED may be formed on the second planarization layer 322. The light emitting element ED may include the pixel electrode PE, the intermediate layer EL, and the common electrode CE. A light emitting area of the light emitting element ED may be formed by an area where the pixel electrode PE, the intermediate layer EL, and the common electrode CE overlap and contact each other.

The pixel electrode PE may be disposed on the second planarization layer 322, and a bank 331 may be disposed on the pixel electrode PE. An opening of the bank 331 may expose a portion of the pixel electrode PE to form a light emitting area. For example, the opening of the bank 331 may overlap with the portion of the pixel electrode PE. The bank 331 may include, but is not limited to, an inorganic insulating material such as silicon nitride (SiNx) or silicon oxide (SiOx), or an organic insulating material such as a benzocyclobutene-based resin, an acrylic-based resin, or an imide-based resin. A spacer 332 may be disposed on the bank 331.

The intermediate layer EL of the light emitting element ED may be disposed on a portion of the pixel electrode PE and the bank 331. The common electrode CE may be disposed on the intermediate layer EL.

Referring to FIG. 3, the encapsulation part may be disposed on the light emitting element part, and be disposed on the common electrode CE. The encapsulation part may include an encapsulation layer 200 disposed on the common electrode CE.

The encapsulation layer 200 can prevent moisture or oxygen from penetrating into the light emitting element ED. For example, the encapsulation layer 200 can prevent moisture or oxygen from penetrating into an organic material included in the intermediate layer EL of the light emitting element ED. For example, the encapsulation layer 200 may be in the form of a single layer or multilayer, but aspects of the present disclosure are not limited thereto.

Referring to FIG. 3, for example, the encapsulation layer 200 may include a first encapsulation layer 341, a second encapsulation layer 342, and a third encapsulation layer 343. The encapsulation layer 200 may include an inorganic layer including an inorganic insulating material. The encapsulation layer 200 may include an organic layer including an organic insulating material. The encapsulation layer 200 may include an inorganic layer and an organic layer.

The first encapsulation layer 341 and the third encapsulation layer 343 may include, for example, an inorganic layer, and the second encapsulation layer 342 may include, for example, an organic layer. Among the first encapsulation layer 341, the second encapsulation layer 342, and the third encapsulation layer 343, the second encapsulation layer 342 may be the thickest.

The first encapsulating layer 341 may include an inorganic insulating material that can be deposited at a low temperature. For example, the first encapsulation layer 341 may be silicon nitride (SiNx), silicon oxide (SiOx), silicon oxynitride (SiON), aluminum oxide (Al₂O₃), or the like. Since the first encapsulation layer 341 is deposited in a low temperature atmosphere, the first encapsulation layer 341 can prevent the intermediate layer EL including an organic material vulnerable to a high temperature atmosphere from being damaged during the deposition process.

For example, the second encapsulation layer 342 may have a smaller area than the first encapsulation layer 341. In this example, the second encapsulation layer 342 may be disposed such that it exposes both ends of the first encapsulation layer 341. The second encapsulation layer 342 can serve as a buffer to relieve stress between layers in a situation where the display device 100 is bent, and also serve to enhance flattening performance. The second encapsulation layer 342 may be referred to as a material compensation layer. For example, the second encapsulating layer 342 may include an organic insulating material, such as an acrylic resin, an epoxy resin, a polyimide, polyethylene, silicon oxycarbon (SiOC), or the like. For example, the second encapsulating layer 342 may be formed by an inkjet process.

The third encapsulation layer 343 may be disposed on the substrate 111 on which the second encapsulation layer 342 is disposed, and cover respective upper surfaces and at least one side surfaces of the second encapsulation layer 342 and the first encapsulation layer 341. The third encapsulation layer 343 can minimize or block external moisture or oxygen from penetrating into the first encapsulation layer 341 and the second encapsulation layer 342. For example, the third encapsulation layer 343 may include an inorganic insulating material such as silicon nitride (SiNx), silicon oxide (SiOx), silicon oxide nitride (SiON), aluminum oxide (Al₂O₃), or the like.

In discussions that follow, for convenience of description for configurations equal, substantially equal to the configurations described above, the thin film transistors (TFT1 and TFT2), the storage capacitor Cst, and the encapsulation layer 200 are omitted, and the substrate 111, the first buffer layer 311, the first gate insulating layer 312, the first interlayer insulating layer 313, the second buffer layer 314, the second gate insulating layer 315, and the second interlayer insulating layer 316 are collectively expressed as a TFT array substrate 310, and the first planarization layer 321 and the second planarization layer 322 are collectively expressed as the planarization layer 320. It should be noted that although the omitted configurations are the same or substantially the same, the structure is not necessarily limited to that illustrated in FIG. 3.

In one or more aspects, a touch sensor may be embedded in the display panel 110. In this configuration, the display panel 110 may include a touch sensor layer 210 disposed on the encapsulation layer 200.

Referring to FIG. 3, the touch sensor layer 210 may include a plurality of touch electrodes, and include touch sensor metals TSM and bridge metals BRG to form the plurality of touch electrodes. Herein, a layer where the touch sensor metals TSM are disposed may also be referred to as a sensor metal layer TSM, and a layer where the bridge metals BRG are disposed may also be referred to as a bridge metal layer BRG.

The touch sensor layer 210 may further include one or more insulating layers such as a sensor buffer layer 351 on the encapsulation layer 200, a sensor interlayer insulating layer 352 on the sensor buffer layer 351, and/or a sensor protection layer 353 on the sensor interlayer insulating layer 352. In one or more aspects, the sensor buffer layer 351 may be omitted.

The bridge metals BRG may be disposed between the sensor buffer layer 351 and the sensor interlayer insulation layer 352, and the touch sensor metals TSM may be disposed between the sensor interlayer insulation layer 352 and the sensor protection layer 353.

Each of the plurality of touch electrodes may be configured with one or more touch sensor metals TSM. Each of a plurality of touch electrodes may be a mesh-type electrode configured to have a mesh and having a plurality of openings.

For example, the plurality of touch electrodes may include at least one first touch electrode TE1 and at least one second touch electrode TE2. Two or more touch sensor metals TSM, or two or more parts of one touch sensor metal TSM, included in each first touch electrode TE1 or each second touch electrode TE2 may be electrically connected through one or more bridge metals BRG. For example, touch sensor metals TSM spaced apart from each other may be electrically connected by one or more bridge metals BRG, and thereby, one first touch electrode TE1 or one second touch electrode TE2 can be formed.

The bridge metals BRG may be disposed on the sensor buffer layer 351, and the sensor interlayer insulating layer 352 may be disposed on the bridge metals BRG. The touch sensor metals TSM may be disposed on the sensor interlayer insulating layer 352. One or more of the touch sensor metals TSM or a corresponding portion of each of the touch sensor metals TSM may be connected to a corresponding bridge metal BRG through a hole of the sensor interlayer insulating layer 352.

Referring to FIG. 3, the touch sensor metals TSM and the bridge metals BRG may be disposed not to overlap with the light emitting element ED. The touch sensor metals TSM and the bridge metals BRG may overlap with the bank 331.

A plurality of touch sensor metals TSM may form one touch electrode, and be disposed in a mesh form and electrically connected to each other. One or more of the touch sensor metals TSM or a portion of each of the touch sensor metals TSM may be electrically connected to the remaining one or more touch sensor metals TSM or the remaining portion of each of the touch sensor metals TSM through one or more bridge metals BRG, and thereby, one touch electrode can be formed.

The sensor protection layer 353 may be disposed such that it covers the touch sensor metals TSM and the bridge metals BRG.

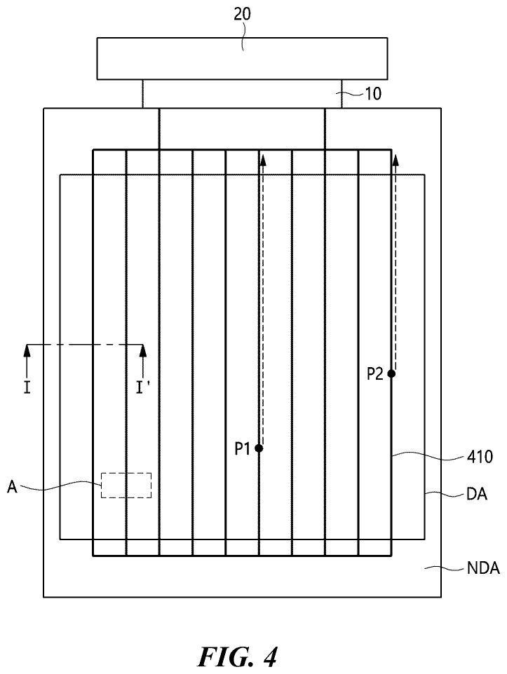

FIG. 4 is an example plan view of the display device 100 according to aspects of the present disclosure. In discussions that follow for the configuration of FIG. 4, discussions for features and configurations equal, substantially equal, or similar to the features and configurations described with reference to FIGS. 1 to 3 are omitted or briefly described for conciseness.

Referring to FIG. 4, in one or more example embodiments, the display device 100 may include the substrate 111, a printed circuit board 20 configured to generate electrical signals and supply a common voltage and the like while being located in an area outside of the substrate 111, and a flexible circuit board or connector 10 configured to connect the printed circuit board 20 and the substrate 111 to each other.

In the display device, a common electrode CE may be disposed such that it extends from the display area DA to the non-display area NDA around an outer edge of the display area DA. For example, the common electrode CE may be formed integrally in the whole display area DA and a portion of the non-display area NDA outside of the display area DA.

In one or more aspects, the display panel 110 may include a structure in which a common voltage line 410 and the common electrode CE are electrically connected through a connection electrode and the like in the display area DA, and thereby, can provide advantages of preventing a voltage drop of a common voltage VSS applied to the common electrode CE and improving an unevenness in luminance between areas in the display area DA. For example, a structure in which the common electrode CE and a power supply voltage line electrically connect each other through a connection electrode and the like may be disposed in the non-display area NDA. However, this implementation may act as a hindrance in reducing a width of a bezel of the display panel 110 or the display device 100, which is the non-display area NDA, and therefore, it may be difficult to implement the display panel 110 or the display device 100 with a narrow bezel.

The display area DA may include a plurality of light emitting areas spaced apart, or independently spaced apart, by a plurality of subpixels disposed in the display area DA. In addition, common voltage lines 410 may be disposed to be spaced apart from each other in the display area DA. FIG. 4 illustrates an example in which common voltage lines 410 are disposed in a first direction (e.g., a column direction), but aspects of the present disclosure are not limited thereto. For example, the common voltage lines 410 may be disposed in a second direction (e.g., a row direction). In another example, the common voltage lines 410 may include both one or more lines running in the first direction and one or more lines running in the second direction.

Referring to FIG. 4, the common voltage lines 410 may not be disposed in a second non-display area located outside of the display area DA in the second direction and a fourth non-display area located outside of the display area DA in a direction opposite to the second direction. In one or more aspects, a portion of at least one of the common voltage lines 410 may be disposed in a first non-display area located outside of the display area DA in the first direction and a third non-display area located outside of the display area DA in a direction opposite to the first direction.

For example, referring to FIG. 4, a common voltage VSS may be applied to the common electrode CE in an area formed along a common voltage line 410 connected to the common electrode CE from location P1 and an area formed along another common voltage line 410 connected to the common electrode CE from location P2, in the display area DA. Accordingly, light emitting elements ED disposed in subpixels SP respectively located in the area formed along the common voltage line 410 connected to the common electrode CE at location P1 and in the area formed along the common voltage line 410 connected to the common electrode CE at location P2 can be provided with an equal (or substantially equal) amount of current without a change in an amount of current by the supply of the common voltage VSS with a substantially equal level without a voltage drop at the common electrode CE. This may mean that the corresponding light emitting elements ED may be provided with a substantially equal amount of current in any of the area formed along the common voltage line 410 connected to the common electrode CE at location P1 and the area formed along the common voltage line 410 connected to the common electrode CE at location P2. Thereby, a difference in luminance caused by a difference in amounts of driving current may not occur when the light emitting elements ED are driven.

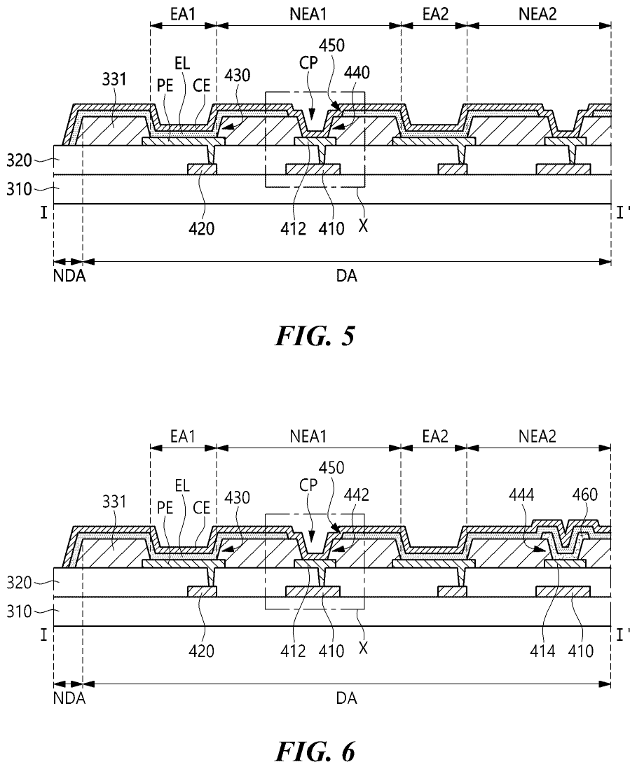

FIG. 5 is an example cross-sectional view taken along line I-I′ of FIG. 4. In discussions that follow for the configuration of FIG. 5, discussions for features and configurations equal, substantially equal, or similar to the features and configurations described with reference to FIGS. 1 to 4 are omitted or briefly described for conciseness.

Referring to FIG. 5, in one or more example embodiments, the display device 100 may include the display area DA and the non-display area NDA. The display area DA may include at least one light emitting area EA1 and EA2 and at least one non-light emitting area NEA1 and NEA2. The non-display area NDA may be formed to surround the display area DA.

A first light emitting area EA1 among light emitting areas defined in the display area DA may include a pixel electrode PE electrically connected to a thin film transistor, an intermediate layer EL on the pixel electrode PE, and a common electrode CE on the intermediate layer EL. The first light emitting area EA1 may correspond to a first opening 430 of a bank 331. A portion of the pixel electrode PE may be exposed in the first opening 430 of the bank 331.

A first non-light emitting area NEA1 among non-light emitting areas defined in the display area DA may mean an area except for the first light emitting area, and a common voltage line 410 and a conductive pattern 412 may be disposed in the first non-light emitting area NEA1. A second opening 440 of the bank 331 and a third opening 450 of the intermediate layer EL may be disposed in the first non-light emitting area NEA1. The second opening 440 and the third opening 450 may be located to overlap with each other.

Referring to FIGS. 4 and 5, a plurality of common voltage lines 410 may be disposed in the display area DA, and pixel electrodes PE may be disposed in the light emitting areas EA, respectively, in the display area DA. At least one of a plurality of conductive patterns 412 electrically connected to at least one of the plurality of common voltage lines 410 may be disposed in at least one of the non-light emitting areas NEA1 and NEA2. The bank 331 may include the first opening 430 located to correspond to the first light emitting area EA1 and the second opening 440 located to correspond to a portion of a conductive pattern 412. The intermediate layer EL may be disposed on the pixel electrode PE and the bank 331, and may include the third opening 450 disposed to correspond to the second opening 440. The common electrode CE may be disposed on the intermediate layer EL and the bank 331, and may be electrically connected to the conductive pattern 412 through the second opening 440 and the third opening 450.

A metal pattern 420 may be electrically connected to the pixel electrode PE. For example, the metal pattern 420 may be a source electrode or a drain electrode of a thin film transistor. For example, the metal pattern 420 may be a relay electrode RE for electrically connecting the thin film transistor and the pixel electrode PE to each other.

Referring to FIG. 5, common voltage lines 410 and the common electrode CE may be electrically connected in the non-light emitting areas in the display area DA. Each common voltage line 410 and the common electrode CE may be electrically connected by a corresponding conductive pattern 412. An area where each common voltage line 410 and the common electrode CE are electrically directly connected or coupled via the conductive pattern 412 may be referred to as a cathode contact area CP.

Referring to FIGS. 4 and 5, cathode contact areas CP may be located in the display area DA, and thereby, a common voltage VSS can be supplied to the display area DA. In this structure, even a portion of the common electrode CE located at a central portion of the display area DA far from an edge portion thereof can be supplied with the common voltage VSS by the common voltage lines 410, and thereby, the common voltage can be maintained uniformly without being reduced. Accordingly, the display device 100 can provide an advantage of maintaining uniformly the voltage of the common electrode CE, and thereby improving the luminance uniformity in the large area.

Referring to FIG. 5, the second opening 440 and third opening 450 may be located to overlap with each other. A width of the second opening 440 may be smaller than a width of the third opening 450. The conductive pattern 412, the second opening 440, and the third opening 450 may be located to overlap with each other. For example, the cathode contact area CP may be located in an area where the conductive pattern 412, the second opening 440, and the third opening 450 overlap with each other. For example, the cathode contact area CP may be located in an area where the common voltage line 410, the conductive pattern 412, the second opening 440, and the third opening 450 overlap with each other. For example, the cathode contact area CP may be located in an area where the common voltage line 410, the conductive pattern 412, the second opening 440, the third opening 450, and the common electrode CE overlap with each other.

Referring to FIG. 5, the conductive pattern 412 and the common electrode CE may contact each other in the second opening 440. For example, in the second opening 440, the common electrode CE may contact at least one side surface (e.g., at least one inclined surface) of the bank 331 and an upper surface of the conductive pattern 412. The common electrode CE may contact all of the at least one side surface of the bank 331 in the second opening 440. The common electrode CE may contact a portion of the upper surface of the conductive pattern 412 in the second opening 440.

Referring to FIG. 5, the common electrode CE may contact the bank 331 and the intermediate layer EL in the third opening 450. For example, the common electrode CE may contact an upper surface of the bank 331 and at least one side surface (e.g., at least one inclined surface) of the intermediate layer EL in the third opening 450. The common electrode CE may contact a portion of the upper surface of the bank 331 in the third opening 450. The common electrode CE may contact all of the at least one side surface of the intermediate layer EL in the third opening 450.

In the non-light emitting area, the intermediate layer EL may include a first common intermediate layer COM1 and a second common intermediate layer COM2. Each of the first common intermediate layer COM1 and the second common intermediate layer COM2 may be disposed to be disconnected in the second opening 440 and the third opening 450.

The intermediate layer EL may further include an emission layer EML between the first common intermediate layer COM1 and the second common intermediate layer COM2. The emission layer EML may be disposed to be disconnected in the second opening 440 and the third opening 450.

The intermediate layer EL may be in the form of a single layer including one emission layer EML, but aspects of the present disclosure are not limited thereto. For example, the intermediate layer EL may have a tandem structure in which a plurality of stacks are disposed, and a charge generation layer is disposed between the plurality of stacks. In one or more aspects, the tandem structure is not limited to a two-stack structure, and may include a multi-stack structure having three or more stacks.

The conductive pattern 412 may include a transparent conductive layer or an opaque conductive layer. For example, the conductive pattern 412, which is a transparent conductive layer, may include a material having a relatively high work function value, such as indium-tin-oxide (ITO) or indium-zinc-oxide (IZO). The conductive pattern 412, which is an opaque conductive layer, may be in the form of a single layer including one selected from the group of silver (Ag), aluminum (Al), copper (Cu), molybdenum (Mo), titanium (Ti), nickel (Ni), chromium (Cr), tungsten (W), and an alloy of two or more thereof, or in the form of a multilayer including one or more selected from the group of silver (Ag), aluminum (Al), copper (Cu), molybdenum (Mo), titanium (Ti), nickel (Ni), chromium (Cr), tungsten (W), and/or one or more alloys of two or more thereof. For example, the conductive pattern 412 may be located in the same layer as the pixel electrode PE. For example, the conductive pattern 412 may include the same material as the pixel electrode PE.

The common voltage line 410 may be in the form of a single layer including one of molybdenum (Mo), copper (Cu), titanium (Ti), aluminum (Al), chromium (Cr), gold (Au), nickel (Ni), neodymium (Nd), tungsten (W), and an alloy of two or more thereof, or in the form of a multilayer including one or more of molybdenum (Mo), copper (Cu), titanium (Ti), aluminum (Al), chromium (Cr), gold (Au), nickel (Ni), neodymium (Nd), tungsten (W), and/or one or more alloys of two or more thereof. For example, the common voltage line 410 may be located in the same layer as the relay electrode RE. For example, the common voltage line 410 may include the same material as the relay electrode RE. For example, the common voltage line 410 may be located in the same layer as at least one of a gate electrode, a source electrode, and a drain electrode of a thin film transistor. For example, the common voltage line 410 may include the same material as at least one of the gate electrode, the source electrode, and the drain electrode of the thin film transistor.

As the cathode contact area CP electrically connecting the common electrode CE and the common voltage line 410 to each other is disposed in the display area DA, the display device 100 can provide an advantage of improving or reducing an unevenness in luminance between areas in the display area DA.

As the cathode contact area CP electrically connecting the common electrode CE and the common voltage line 410 to each other is disposed in the display area DA, the display device 100 can provide advantages of reducing a distance between subpixels (e.g., a width of a non-light emitting area) and thereby achieving high resolution.

As the cathode contact area CP electrically connecting the common electrode CE and the common voltage line 410 to each other is not disposed in the non-display area NDA, the display device 100 can provide advantages of reducing a width of the bezel, and thereby implementing a narrow bezel.

FIG. 6 is another example cross-sectional view taken along line I-I′ of FIG. 4. In discussions that follow for the configuration of FIG. 6, discussions for features and configurations equal, substantially equal, or similar to the features and configurations described with reference to FIGS. 1 to 5 are omitted or briefly described for conciseness.

The configuration of FIG. 6 may be the same as the configuration of FIG. 5 except that a first non-light emitting area NEA1 may include a cathode contact area CP, and a second non-light emitting area NEA2 may not include a cathode contact structure, and therefore, discussions for the same configuration are not provided for conciseness.

Referring to FIG. 6, a bank 331 may include a first sub-opening 442 and a second sub-opening 444. An intermediate layer EL may be disposed on a pixel electrode PE, the bank 331, and a sacrificial layer 460, and include a third opening 450 located to correspond to the first sub-opening 442. A common electrode CE may be disposed on the intermediate layer EL and the bank 331, and may be electrically connected to a conductive pattern 412 through the first sub-opening 442 and the third opening 450.

Referring to FIG. 6, a cathode contact area CP of the first non-light emitting area NEA1 may include a common voltage line 410, the conductive pattern 412 electrically connected to the common voltage line 410, and the common electrode CE electrically connected to the conductive pattern 412. The cathode contact area CP may be located in an area where the opening of the bank 331 and the opening of the intermediate layer EL overlap with each other. For example, the cathode contact area CP may be located in an area where the first sub-opening 442 of the bank 331 and the third opening 450 of the intermediate layer EL overlap with each other.

Referring to FIG. 6, the first sub-opening 442 and the third opening 450 may be located to overlap with each other. A width of the first sub-opening 442 may be smaller than a width of the third opening 450. For example, the conductive pattern 412, the first sub-opening 442, and the third opening 450 may be located to overlap with each other. For example, the cathode contact area CP may be located in an area where the conductive pattern 412, the first sub-opening 442, and the third opening 450 overlap with each other. For example, the cathode contact area CP may be located in an area where the common voltage line 410, the conductive pattern 412, the first sub-opening 442, and the third opening 450 overlap with each other. For example, the cathode contact area CP may be located in an area where the common voltage line 410, the conductive pattern 412, the first sub-opening 442, the third opening 450, and the common electrode CE overlap with each other.

Referring to FIG. 6, the conductive pattern 412 and the common electrode CE may contact each other in the first sub-opening 442. For example, in the first sub-opening 442, the common electrode CE may contact at least one side surface (e.g., at least one inclined surface) of the bank 331 and an upper surface of the conductive pattern 412. The common electrode CE may contact the whole side surface of the bank 331 in the first sub-opening 442. The common electrode CE may contact a portion of the upper surface of the conductive pattern 412 in the first sub-opening 442.

Referring to FIG. 6, the common electrode CE may contact the bank 331 and the intermediate layer EL in the third opening 450. For example, the common electrode CE may contact an upper surface of the bank 331 and at least one side surface (e.g., at least one inclined surface) of the intermediate layer EL in the third opening 450. The common electrode CE may contact a portion of the upper surface of the bank 331 in the third opening 450. The common electrode CE may contact all of the at least one side surface of the intermediate layer EL in the third opening 450.

Referring to FIG. 6, the bank 331 may include the second sub-opening 444 located spaced apart from the first sub-opening 442 and overlapping with the second non-light emitting area NEA2 or located in the second non-light emitting area NEA2. The first sub-opening 442 may be located to correspond to a portion of the conductive pattern 412.

Referring to FIG. 6, the sacrificial layer 460 may be located in the second sub-opening 444. The second sub-opening 444 may be located such that it is spaced apart from the first sub-opening 442 and overlaps with the second non-light emitting area NEA2.

The cathode contact area CP may be formed through a laser lift-off process using the sacrificial layer 460. For example, when an infrared laser is irradiated to the sacrificial layer 460 and the intermediate layer EL deposited on the conductive pattern 412, the sacrificial layer 460 can absorb the energy of the laser and thereby be heated to a predetermined temperature. Thereafter, the intermediate layer EL located on the sacrificial layer 460 may be removed together with the sacrificial layer 460, and thereby, an area where the cathode contact area CP is to be formed may be formed. For example, the intermediate layer EL may be indirectly removed.

The sacrificial layer 460 may have a lower threshold energy density (TED) than the conductive pattern (414, or a dummy conductive pattern) located under the sacrificial layer 460. For example, when the threshold energy density TED of the sacrificial layer 460 is higher or similar to the threshold energy density TED of the conductive pattern 414, layers located on the conductive pattern 414 may be removed together with the conductive pattern 414 in the laser lift-off process. In an example where the conductive pattern 414 includes the same material in the same layer as the pixel electrode PE, when the laser is irradiated in a degree to which the conductive pattern 414 is removed, the pixel electrode PE may be damaged. Therefore, the threshold energy density TED of the sacrificial layer 460 may be lower than the threshold energy density TED of the conductive pattern 414. The sacrificial layer 460 may include any one of silver (Ag) and magnesium (Mg) or an alloy thereof.

A dummy conductive pattern 414 may be located in the second sub-opening 444 and be located under the sacrificial layer 460. The dummy conductive pattern 414 may be in an electrical floating state. For example, the dummy conductive pattern 414 may not be electrically connected to the common voltage line 410.

The dummy conductive pattern 414 may include a transparent conductive layer or an opaque conductive layer. For example, the dummy conductive pattern 414, which is a transparent conductive layer, may include a material having a relatively high work function value, such as indium-tin-oxide (ITO) or indium-zinc-oxide (IZO). The dummy conductive pattern 414, which is an opaque conductive layer, may be in the form of a single layer including one selected from the group of silver (Ag), aluminum (Al), copper (Cu), molybdenum (Mo), titanium (Ti), nickel (Ni), chromium (Cr), tungsten (W), and an alloy of two or more thereof, or in the form of a multilayer including one or more selected from the group of silver (Ag), aluminum (Al), copper (Cu), molybdenum (Mo), titanium (Ti), nickel (Ni), chromium (Cr), tungsten (W), and/or one or more alloys of two or more thereof. For example, the dummy conductive pattern 414 may be located in the same layer as the pixel electrode PE and the conductive pattern 412. For example, the dummy conductive pattern 414 may include the same material as the pixel electrode PE and the conductive pattern 412.

FIG. 6 illustrates a structure in which the second sub-opening 444, the dummy conductive pattern 414, and the sacrificial layer 460 are disposed in the second non-light emitting area NEA2 to which the common electrode CE and the common voltage line 410 are not connected, but aspects of the present disclosure are not limited thereto. For example, at least one of the second sub-opening 444, the dummy conductive pattern 414, and the sacrificial layer 460 may not be disposed in the second non-light emitting area NEA2.

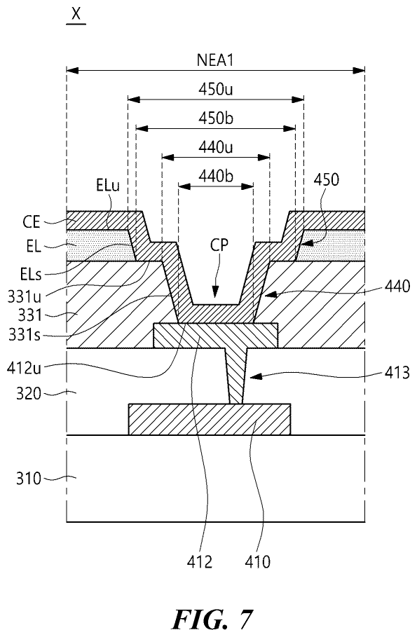

FIG. 7 is an example enlarged cross-sectional view of area X in FIG. 5. In discussions that follow for the configuration of FIG. 7, discussions for features and configurations equal, substantially equal, or similar to the features and configurations described with reference to FIGS. 1 to 6 are omitted or briefly described for conciseness.

FIG. 7 shows an enlarged view of the cathode contact area CP disposed in the non-light emitting area NEA in the display area DA.

Referring to FIG. 7, the common voltage line 410 and the conductive pattern 412 may be located to overlap with each other. The conductive pattern 412 may be connected to the common voltage line 410 through a contact hole 413 of a planarization layer 320. The second opening 440 of the bank 331 and the third opening 450 of the intermediate layer EL may be located to overlap with each other.

Referring to FIG. 7, the second opening 440 may have an inverse taper shape in the cross-sectional view. For example, a width of the second opening 440 may increase as it moves away from a TFT array substrate 310 in a direction perpendicular to a surface of the TFT array substrate. For example, a width of a lower portion 440b of the second opening 440 may be smaller than a width of an upper portion 440u of the second opening 440. For example, the width of the upper portion 440u of the second opening 440 may be larger than the width of the lower portion 440b of the second opening 440.

The third opening 450 may have an inverse taper shape in the cross-sectional view. For example, a width of the third opening 450 may increase as it moves away from the TFT array substrate 310 in the direction perpendicular to the surface of the TFT array substrate. For example, a width of a lower portion 450b of the third opening 450 may be smaller than a width of an upper portion 450u of the third opening 450. For example, the width of the upper portion 450u of the third opening 450 may be larger than the width of the lower portion 450b of the third opening 450.

Referring to FIG. 7, the width of the second opening 440 may be smaller than the width of the third opening 450. For example, the width of the upper portion 440u of the second opening 440 may be smaller than the width of the lower portion 450b of the third opening 450. In the cathode contact area CP, the widths of the openings may increase in the following order: the width of the lower portion 440b of the second opening 440, the width of the upper portion 440u of the second opening 440, the width of the lower portion 450b of the third opening 450, and the width of the upper portion 450u of the third opening 450.

Referring to FIG. 7, the conductive pattern 412 and the common electrode CE may contact each other in the second opening 440. For example, in the second opening 440, the common electrode CE may contact at least one side surface 331s of the bank 331 and an upper surface 412u of the conductive pattern 412. The common electrode CE may contact all of the at least one side surface 331s of the bank 331 in the second opening 440. The common electrode CE may contact a portion of the upper surface 412u of the conductive pattern 412 in the second opening 440.

Referring to FIG. 7, the common electrode CE may contact the bank 331 and the intermediate layer EL in the third opening 450. For example, the common electrode CE may contact an upper surface 331u of the bank 331 and at least one side surface ELs of the intermediate layer EL in the third opening 450. The common electrode CE may contact a portion of the upper surface 331u of the bank 331 in the third opening 450. The common electrode CE may extend from the upper surface ELu of the intermediate layer EL and contact all of the at least one side surface ELs of the intermediate layer EL in the third opening 450.

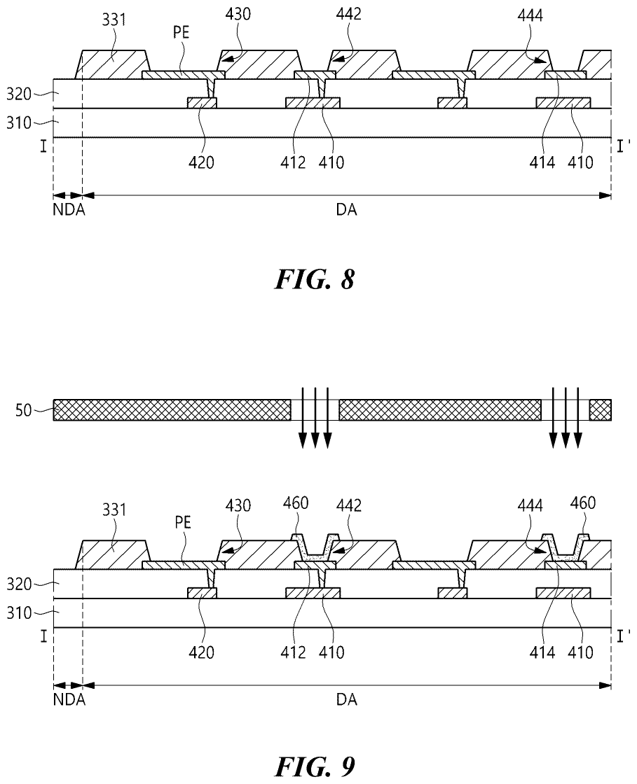

FIGS. 8 to 13 illustrate an example process of manufacturing the display device according to aspects of the present disclosure. In discussions that follow for the configuration of FIGS. 8 to 13, discussions for features and configurations equal, substantially equal, or similar to the features and configurations described with reference to FIGS. 1 to 7 are omitted or briefly described for conciseness.

Referring to FIG. 8, a TFT array substrate 310 may be formed, and a common voltage line 410 and a metal pattern 420 on the TFT array substrate 310 may be formed by a patterning process. Thereafter, a planarization layer 320 may be formed, and contact holes may be formed in portions of the planarization layer 320 corresponding to a portion of the common voltage line 410 and overlapping with the metal pattern 420, respectively. Pixel electrodes PE connected to the metal pattern 420 and a conductive pattern 412 connected to the common voltage line 410 may be formed to be through the contact holes, respectively. In this configuration, a dummy conductive pattern 414 may be formed to be electrically floated with the common voltage line 410 located under the dummy conductive pattern 414. A bank 331 may be formed to form a first opening 430, a first sub-opening 442, and a second sub-opening 444. In one or more aspects, the dummy conductive pattern 414 may not be formed.

Referring to FIG. 9, a sacrificial layer 460 may be formed in an area overlapping with the conductive pattern 412 and the dummy conductive pattern 414 using a mask 50. In one or more aspects, the sacrificial layer 460 may not be formed in an area where the dummy conductive pattern 414 is not formed and an area where the conductive pattern 412 is formed. The sacrificial layer 460 may be formed using a fine metal mask (FMM). When the sacrificial layer 460 is formed using the fine metal mask (FMM), a distance between subpixels can be reduced, and thereby, the display device 100 can provide an advantage of having a high resolution.

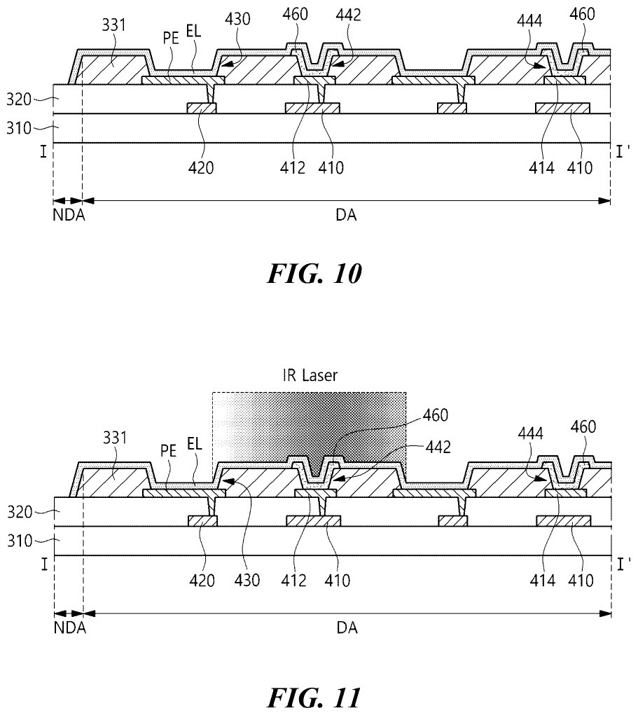

Referring to FIG. 10, an intermediate layer EL may be deposited. The intermediate layer EL may include a first common intermediate layer, an emission layer, and a second common intermediate layer. The first common intermediate layer, the emission layer, and the second common intermediate layer may be sequentially deposited in this order. In this configuration, for example, the first common intermediate layer and the second common intermediate layer may be deposited on the entire surface. The emission layer may be deposited on a subpixel basis to correspond to each emission color, or deposited on the entire surface.

Referring to FIG. 11, an infrared laser may be irradiated to an area where the common voltage line 410 and the conductive pattern 412 are electrically connected. The laser may be irradiated to an area wider than an area where the sacrificial layer 460 is disposed. The laser may be irradiated with energy density higher than the threshold energy density TED of the sacrificial layer 460 and lower than the threshold energy density TED of the dummy conductive pattern 414.

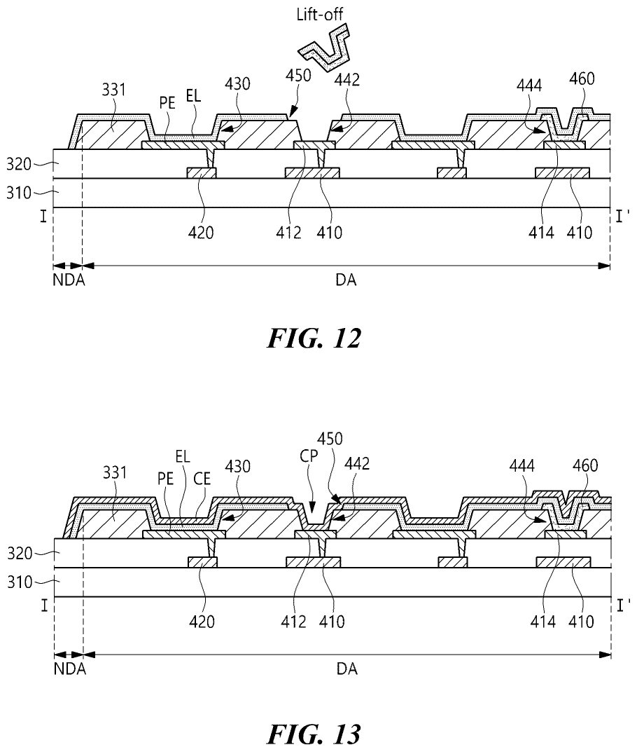

Referring to FIG. 12, the intermediate layer EL on the sacrificial layer 460 may be removed or lift off together with the sacrificial layer 460 by the irradiation of the laser. In this case, a third opening 450 from which a portion of the intermediate layer EL is removed may be formed on the upper surface of the bank 331 overlapping with the first sub-opening 442.

Referring to FIG. 13, a common electrode CE may be deposited on the entire surface, and thereby, a light emitting element ED and a cathode contact area CP can be formed.

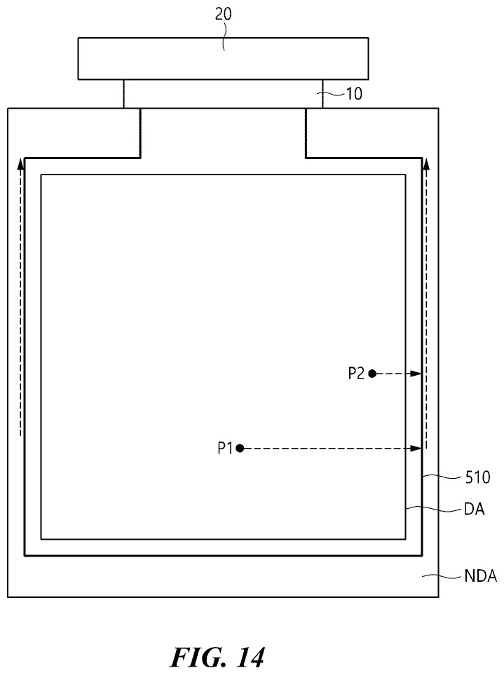

FIG. 14 is a plan view of a normal display device. In discussions that follow for the configuration of FIG. 14, discussions for features and configurations equal, substantially equal, or similar to the features and configurations described with reference to FIGS. 1 to 13 are omitted or briefly described for conciseness.

Referring to FIG. 14, the normal display device may be formed by extending a common electrode CE to the non-display area NDA, and the common electrode CE may be connected to a power supply voltage line 510 and a connection electrode, and the like in the non-display area NDA. In this structure, the common electrode CE may be supplied with a common voltage only from the power voltage line 510 in an outer area, and the common electrode CE disposed in the entire area of the display area DA may have a high surface resistance. In this case, a voltage drop may occur due to the resistance of area P1 and area P2, and a large RC delay due to the resistance difference may occur in an area far from an area to which a voltage or current is applied or supplied when compared to an outer area close to the area to which the voltage or current is applied or supplied. Thereby, a difference in luminance between areas in the display area DA may occur.

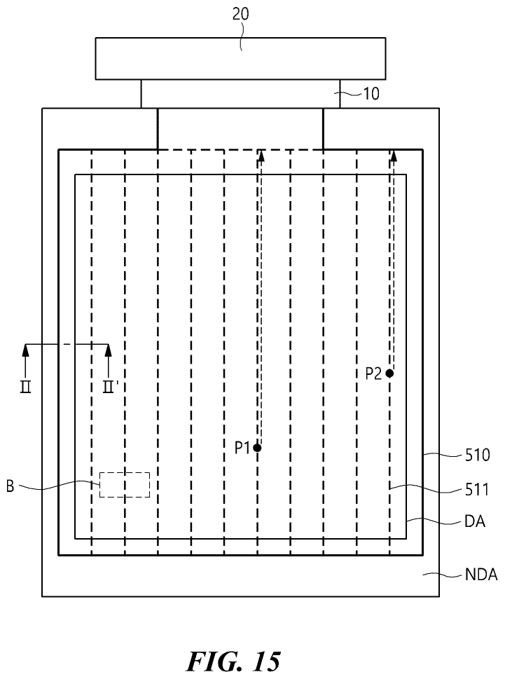

FIG. 15 is another plan view of a normal display device. In discussions that follow for the configuration of FIG. 15, discussions for features and configurations equal, substantially equal, or similar to the features and configurations described with reference to FIGS. 1 to 14 are omitted or briefly described for conciseness.

Referring to FIG. 15, the normal display device may compensate for a difference in luminance by a structure where a power supply voltage line 510 is disposed in the non-display area NDA and an auxiliary line 511 is disposed in the display area DA. For example, a voltage drop due to the resistance of area P1 and area P2 in the display area DA may be prevented. However, a cathode contact area illustrated in FIG. 15 may be formed by laser drilling, which may act as a limitation to reducing a distance between subpixels. In addition, as the power voltage line 510 is disposed in the non-display area NDA, this may act as a limitation to reducing a bezel width.

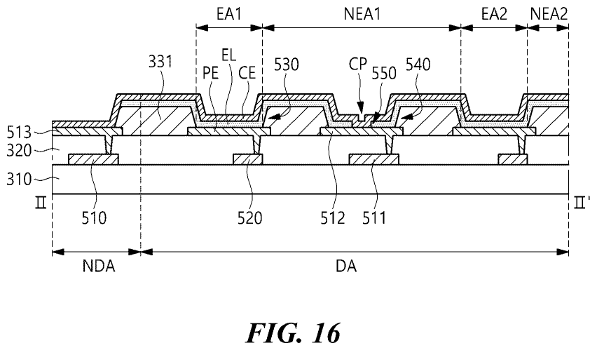

FIG. 16 is a cross-sectional view taken along line II-II′ of FIG. 15. In discussions that follow for the configuration of FIG. 16, discussions for features and configurations equal, substantially equal, or similar to the features and configurations described with reference to FIGS. 1 to 15 are omitted or briefly described for conciseness.

Referring to FIG. 16, the normal display device may have a structure where a cathode contact area CP is disposed in a first non-light emitting area NEA1.

Referring to FIG. 16, a bank 331 may include a first opening 530 overlapping with a first light emitting area EA1 and a second opening 540 overlapping with the cathode contact area CP. An intermediate layer EL may include a third opening 550 located to overlap with the second opening 540.

Referring to FIG. 16, the cathode contact area CP of the first non-light emitting area NEA1 may include an auxiliary line 511, a connection electrode 512 electrically connected to the auxiliary line 511, and a common electrode CE electrically connected to the connection electrode 512. In addition, the non-display area NDA may include a power supply voltage line 510, a connection electrode 513 electrically connected to the power supply voltage line 510, and the common electrode CE electrically connected to the connection electrode 513.

Referring to FIG. 16, the second opening 540 and third opening 550 may be located to overlap with each other. A width of the second opening 540 may be greater than a width of the third opening 550. The third opening 550 may be located in the second opening 540.

Referring to FIG. 16, the connection electrode 512 and the common electrode CE may contact each other in the second opening 540. For example, the connection electrode 512 and the common electrode CE may contact each other in the third opening 550 located in the second opening 540. The connection electrode 512 may be disposed to contact the intermediate layer EL in the second opening 540.

The third opening 550 illustrated in FIG. 16 may be formed by a laser drilling process. The laser drilling process may be a process of directly removing a portion of the intermediate layer EL by irradiating an ultraviolet laser to the intermediate layer EL. In this case, the connection electrode 512 located under the intermediate layer EL may be damaged by the ultraviolet laser. In addition, since the ultraviolet laser can react with components including organic materials such as the bank or a planarization layer as well as the intermediate layer EL, it may be necessary to irradiate the laser only within a certain area. Accordingly, a laser irradiation area wider than an area where the cathode contact area is to be formed may be needed. Based on this structure, it may be disadvantageous to manufacture a display device with high resolution due to the laser drilling process.

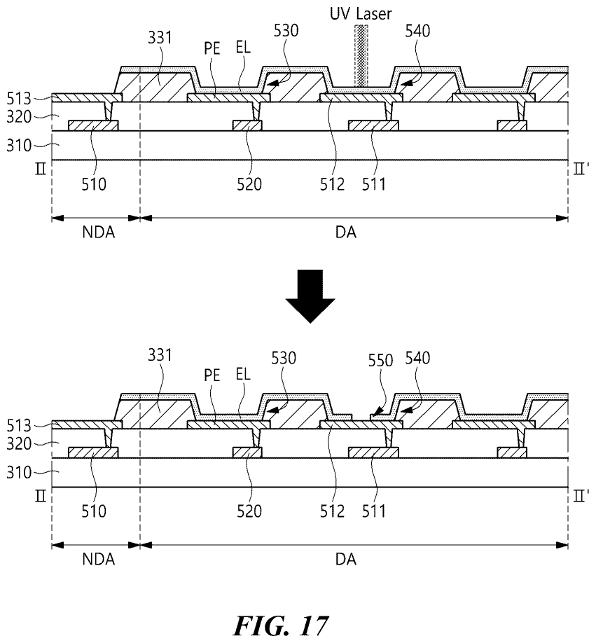

FIG. 17 illustrates a process of the display device illustrated in FIG. 16. In discussions that follow for the configuration of FIG. 17, discussions for features and configurations equal, substantially equal, or similar to the features and configurations described with reference to FIGS. 1 to 16 are omitted or briefly described for conciseness.

FIG. 17 is a process of forming the cathode contact area CP of the display device illustrated in FIG. 16 using the laser drilling process.

Referring to FIG. 17, after depositing the intermediate layer EL, an ultraviolet laser may be irradiated to an area where the cathode contact area CP is to be formed. Since the energy density of the ultraviolet laser is high, the connection electrode 512 located under the intermediate layer EL may be damaged. If the energy density is low, the intermediate layer EL may not be removed. In addition, the ultraviolet laser may be needed to be irradiated at a certain distance from these configurations not to react with the bank or the planarization layer. Accordingly, a width of the connection electrode 512 located under the intermediate layer EL may be desired to be at a certain level or more. Therefore, a structure formed by the laser drilling process can be disadvantageous for manufacturing a display device having a high resolution.

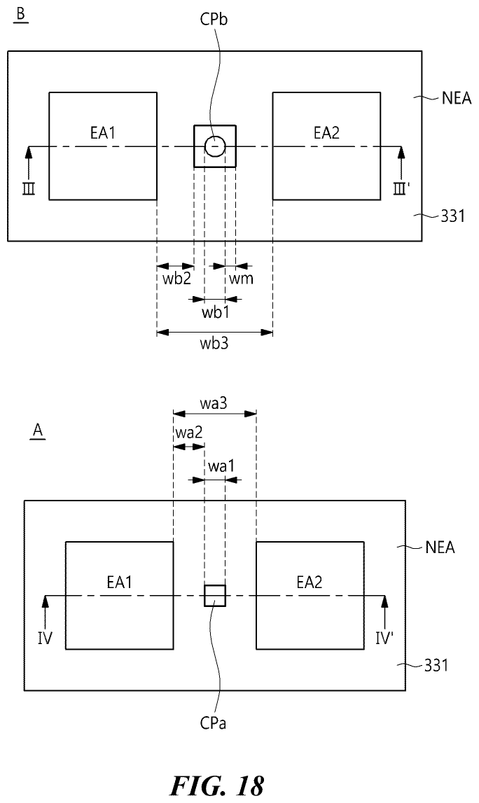

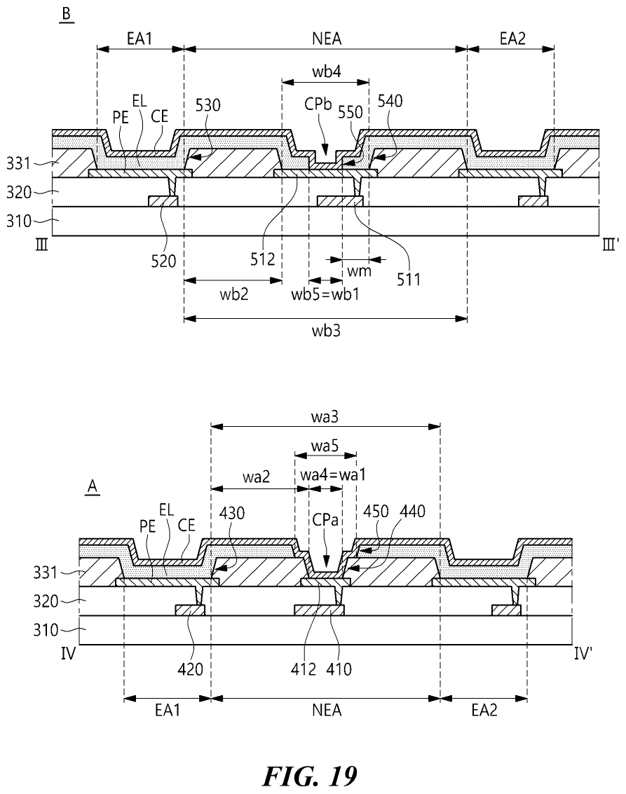

FIG. 18 is example cross-sectional views of area A in FIG. 4 and area B in FIG. 15. FIG. 19 is example cross-sectional views taken along line III-III′ and line IV-IV′ of FIG. 18. In discussions that follow for the configurations of FIGS. 18 and 19, discussions for features and configurations equal, substantially equal, or similar to the features and configurations described with reference to FIGS. 1 to 17 are omitted or briefly described for conciseness.

FIGS. 18 and 19 are plan views and cross-sectional views comparing the normal display device B using the laser drilling process and the display device A according to the example embodiments of the present disclosure using the laser lift-off process.

Referring to FIG. 18, in the normal display device B, a width wb1 may mean a distance of a cathode contact area. A width wb2 may mean a minimum distance between light emitting areas (EA1 and EA2) and a connection electrode 512. A width wb3 may mean a distance between the light emitting areas (EA1 and EA2). A width wm may mean a minimum distance so that the bank or the planarization layer does not react in the laser drilling process. According to these configurations, in the normal display device B, the width wb3 between the light emitting areas (i.e., the width between the subpixels) may be expressed as (2*(wb2+wm)+wb1).

Referring to FIG. 18, in the display device A according to the example embodiments of the present disclosure, a width wa1 may mean a distance of a cathode contact area. A width wa2 may mean a minimum distance between light emitting areas (EA1 and EA2) and a conductive pattern 412. A width wa3 may mean a distance between the light emitting areas (EA1 and EA2). According to these configurations, in the display device A according to the example embodiments of the present disclosure, the width wa3 between the light emitting areas (i.e., the width between the subpixels) may be expressed as (2*wa2+wa1).

Referring to FIG. 19, in the normal display device B, a width wb4 may mean a width of the second opening 540 of the bank 331, and a width wb5 may mean a width of the third opening 550 of the intermediate layer EL. In the normal display device B, the width wb1 of the cathode contact area CPb may be substantially the same as the width wb5 of the third opening 550.

Referring to FIG. 19, in the display device A according to the example embodiments of the present disclosure, a width wa4 may mean a width of the second opening 440 of the bank 331, and the width wa5 may mean a width of the third opening 450 of the intermediate layer EL. In the display device A according to the example embodiments of the present disclosure, the width wa1 of the cathode contact area CPa may be substantially the same as the width wa4 of the second opening 450.

Referring to FIGS. 18 and 19, when a distance of cathode contact area and a minimum distance between a light emitting area and a connection electrode (or a conductive pattern) are set to the same size in the normal display device B and the display device A according to the example embodiments of the present disclosure, the distance between subpixels in the display device A according to the example embodiments of the present disclosure can be reduced by 2*wb2. Thereby, the display device A according to the example embodiments of the present disclosure can provide an advantage of having a high resolution.

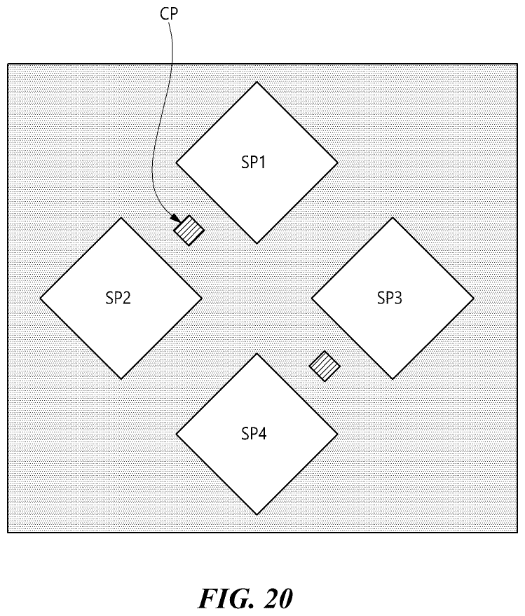

FIGS. 20 to 22 illustrate example plan views of the display device 100 according to aspects of the present disclosure. In discussions that follow for the configuration of FIGS. 20 to 22, discussions for features and configurations equal, substantially equal, or similar to the features and configurations described with reference to FIGS. 1 to 19 are omitted or briefly described for conciseness.

Referring to FIG. 20, in one or more example embodiments, the display device 100 may include a cathode contact area CP between subpixels SP.

The subpixels SP may include first to fourth subpixels (SP1 to SP4), but aspects of the present disclosure are not limited thereto. The first subpixel SP1 may be a red subpixel emitting red light, the second subpixel SP2 may be a blue subpixel emitting blue light, the third subpixel SP3 may be a green subpixel emitting green light, and the fourth subpixel SP4 may be a white subpixel emitting white light, but aspects of the present disclosure are not limited thereto.

FIG. 20 illustrates that the cathode contact area CP is a square shape, but aspects of the present disclosure are not limited thereto. For example, the cathode contact area CP may have various shapes such as a circle, an oval, a square, a hexagon, or an octagon.

FIG. 20 illustrates two subpixels SP sharing one cathode contact area CP, but aspects of the present disclosure are not limited thereto. For example, one subpixel SP may have one cathode contact area CP, and two or more subpixels SP may share one cathode contact area CP. For example, subpixels SP and cathode contact areas CP may be alternately arranged in a first direction or the first direction and a second direction.

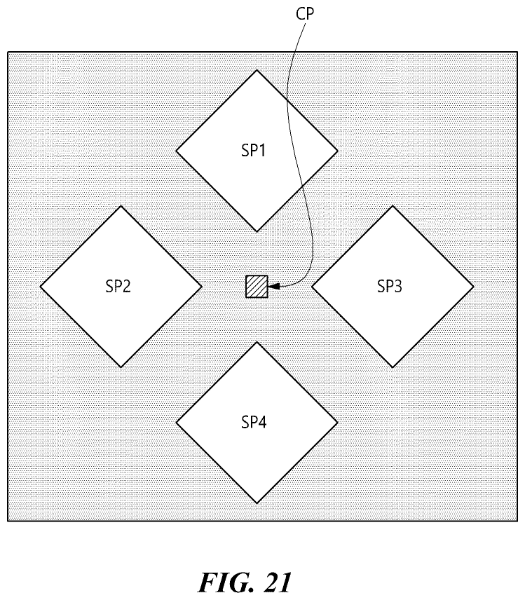

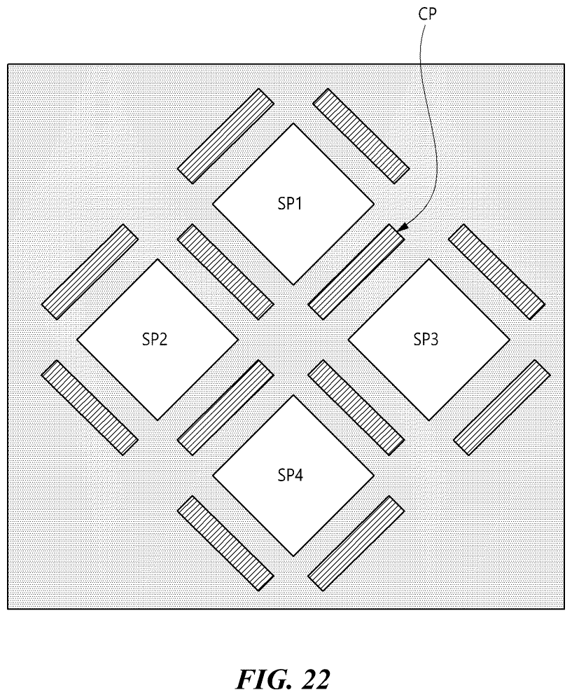

For example, referring to FIG. 21, four subpixels SP may share one cathode contact area CP.

For example, referring to FIG. 22, four cathode contact areas CP may be arranged in a structure where the four cathode contact areas CP are spaced apart from each other and surround one subpixel SP.

According to the one or more aspects described herein, the display device 100 may be provided that is capable of improving an unevenness in luminance between areas in a display area by including a structure where a cathode contact area electrically connecting a common electrode and a common voltage line to each other is disposed in the display area.

According to the one or more aspects described herein, the display device 100 may be provided that is capable of reducing a distance between subpixels (e.g., a width of a non-light emitting area) and thereby achieving high resolution by including a structure where a cathode contact area electrically connecting a common electrode and a common voltage line to each other is disposed in a display area.

According to the one or more aspects described herein, the display device 100 may be provided that is capable of implementing a narrow bezel by reducing a bezel width by including a structure where a cathode contact area electrically connecting a common electrode and a common voltage line to each other is not disposed in a non-display area.

The examples, aspects, and embodiments for the display device 100 and the display panel 110 described herein may be described as follows.

According to the one or more example embodiments described herein, a display device can be provided that includes a substrate including a display area including a light emitting area and a non-light emitting area, and a non-display area surrounding the display area, a common voltage line disposed in the display area, a pixel electrode disposed in the light emitting area, a conductive pattern disposed in the non-light emitting area and electrically connected to the common voltage line, a bank including a first opening located to correspond to the light emitting area and a second opening located to correspond to a portion of the conductive pattern, an intermediate layer located on the pixel electrode and the bank and including a third opening located to correspond to the second opening, and a common electrode disposed on the intermediate layer and the bank and electrically connected to the conductive pattern through the second opening and the third opening.

In one or more aspects, in the display device, the conductive pattern, the second opening and the third opening may be located to overlap with each other.

In one or more aspects, in the display device, a width of the second opening may be less than a width of the third opening.

In one or more aspects, in the display device, in the second opening, the common electrode may contact at least one side surface of the bank and a portion of an upper surface of the conductive pattern.

In one or more aspects, in the display device, in the third opening, the common electrode may contact a portion of an upper surface of the bank and at least one side surface of the intermediate layer.

In one or more aspects, in the display device, each of the second opening and the third opening may have an inverse taper shape. In one or more aspects, a width of an upper portion of the second opening may be less than a width of a lower portion of the third opening.

In one or more aspects, in the display device, in the non-light emitting area, the intermediate layer may include a first common intermediate layer and a second common intermediate layer. In one or more aspects, the first common intermediate layer and the second common intermediate layer may be disposed to be disconnected in the second opening and the third opening.

In one or more aspects, in the display device, the intermediate layer may include an emission layer between the first common intermediate layer and the second common intermediate layer. In one or more aspects, the emission layer may be disposed to be disconnected in the second opening and the third opening.

In one or more aspects, in the display device, the conductive pattern may be located in the same layer as the pixel electrode.

In one or more aspects, the display device may further include a thin film transistor electrically connected to the pixel electrode through a relay electrode. In one or more aspects, the common voltage line may be located in the same layer as the relay electrode.

In one or more aspects, the display device may further include a thin film transistor electrically connected to the pixel electrode. In one or more aspects, the thin film transistor may include a gate electrode, a source electrode, and a drain electrode. In one or more aspects, the common voltage line may be located in the same layer as at least one electrode of the thin film transistor.

According to the one or more example embodiments described herein, a display device can be provided that includes a substrate including a display area including a light emitting area and a non-light emitting area, and a non-display area surrounding the display area, a common voltage line disposed in the display area, a pixel electrode disposed in the light emitting area, a conductive pattern disposed in the non-light emitting area and electrically connected to the common voltage line, a bank including a first opening located corresponding to the light emitting area, a first sub-opening located to correspond to a portion of the conductive pattern, and a second sub-opening located to be spaced from the first sub-opening and located in the non-light emitting area, a sacrificial layer disposed in the second sub-opening, an intermediate layer disposed on the pixel electrode, the bank, and the sacrificial layer, and including a third opening located to correspond to the first sub-opening, and a common electrode disposed on the intermediate layer and the bank, and electrically connected to the conductive pattern through the first sub-opening and the third opening.

In one or more aspects, in the display device, the conductive pattern, the first sub-opening, and the third opening may be located to overlap with each other.

In one or more aspects, in the display device, a width of the first sub-opening may be less than a width of the third opening.

In one or more aspects, in the display device, in the first sub-opening, the common electrode may contact at least one side surface of the bank and a portion of an upper surface of the conductive pattern.

In one or more aspects, in the display device, in the third opening, the common electrode may contact a portion of an upper surface of the bank and at least one side surface of the intermediate layer.

In one or more aspects, in the display device, the sacrificial layer may include one of silver (Ag) and magnesium (Mg) or an alloy thereof.

In one or more aspects, the display device, may further include a dummy conductive pattern located in the second sub-opening and located under the sacrificial layer.

In one or more aspects, in the display device, the pixel electrode, the conductive pattern, and the dummy conductive pattern may be located in the same layer as each other.

In one or more aspects, in the display device, the dummy conductive pattern may be in an electrical floating state.

The above description has been presented to enable any person skilled in the art to make, use and practice the technical features of the present disclosure, and has been provided in the context of a particular application and its requirements as examples. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical features of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate having a display area including a light emitting area and a non-light emitting area, and a non-display area adjacent to the display area;
a common voltage line disposed in the display area;
a pixel electrode disposed in the light emitting area;
a conductive pattern disposed in the non-light emitting area and electrically connected to the common voltage line;
a bank including a first opening corresponding to the light emitting area and a second opening corresponding to a portion of the conductive pattern;
an intermediate layer disposed on the pixel electrode and on the bank, the intermediate layer including a third opening corresponding to the second opening; and
a common electrode disposed on the intermediate layer and the bank, the common electrode being electrically connected to the conductive pattern through the second opening and the third opening.

2. The display device of claim 1, wherein the conductive pattern, the second opening, and the third opening are located to overlap with each other in a plan view.

3. The display device of claim 1, wherein a width of the second opening is less than a width of the third opening.

4. The display device of claim 1, wherein in the second opening, the common electrode contacts at least one side surface of the bank and a portion of an upper surface of the conductive pattern.

5. The display device of claim 1, wherein in the third opening, the common electrode contacts a portion of an upper surface of the bank and at least one side surface of the intermediate layer.

6. The display device of claim 1, wherein each of the second opening and the third opening has an inverse taper shape, and a width of an upper portion of the second opening is less than a width of a lower portion of the third opening.

7. The display device of claim 1, wherein in the non-light emitting area, the intermediate layer comprises a first common intermediate layer and a second common intermediate layer, and the first common intermediate layer and the second common intermediate layer are separated from one another in the second opening and the third opening.

8. The display device of claim 7, wherein the intermediate layer comprises an emission layer between the first common intermediate layer and the second common intermediate layer, and the emission layer is separated from the first and second common intermediate layers in the second opening and the third opening.

9. The display device of claim 1, wherein the conductive pattern is disposed in the same layer as the pixel electrode.

10. The display device of claim 1, further comprising a thin film transistor electrically connected to the pixel electrode through a relay electrode,
wherein the common voltage line is disposed in the same layer as the relay electrode.

11. The display device of claim 1, further comprising a thin film transistor electrically connected to the pixel electrode,
wherein the thin film transistor comprises a gate electrode, a source electrode, and a drain electrode, and the common voltage line is disposed in the same layer as at least one electrode of the thin film transistor.

12. A display device comprising:
a substrate having a display area including a light emitting area and a non-light emitting area, and a non-display area adjacent to the display area;
a common voltage line disposed in the display area;
a pixel electrode disposed in the light emitting area;
a conductive pattern disposed in the non-light emitting area and electrically connected to the common voltage line;
a bank including a first opening corresponding to the light emitting area, a first sub-opening corresponding to a portion of the conductive pattern, and a second sub-opening disposed to be spaced from the first sub-opening and disposed in the non-light emitting area;
a sacrificial layer disposed in the second sub-opening;
an intermediate layer disposed on the pixel electrode, the bank, and the sacrificial layer, and comprising a third opening corresponding to the first sub-opening; and
a common electrode disposed on the intermediate layer and the bank, and electrically connected to the conductive pattern through the first sub-opening and the third opening.

13. The display device of claim 12, wherein the conductive pattern, the first sub-opening, and the third opening are disposed to overlap with each other in a plan view.

14. The display device of claim 12, wherein a width of the first sub-opening is less than a width of the third opening.

15. The display device of claim 12, wherein in the first sub-opening, the common electrode contacts at least one side surface of the bank and a portion of an upper surface of the conductive pattern.

16. The display device of claim 12, wherein in the third opening, the common electrode contacts a portion of an upper surface of the bank and at least one side surface of the intermediate layer.

17. The display device of claim 12, wherein the sacrificial layer comprises one of silver (Ag) and magnesium (Mg) or an alloy thereof.

18. The display device of claim 12, further comprising a dummy conductive pattern disposed in the second sub-opening and located under the sacrificial layer.

19. The display device of claim 18, wherein the pixel electrode, the conductive pattern, and the dummy conductive pattern are disposed in the same layer as each other.

20. The display device of claim 18, wherein the dummy conductive pattern is in an electrical floating state.
